(19) United States
(12) Patent Application Publication
(10) Pub. No.: US 2026/0269849 A1
(43) Pub. Date: Sep. 10, 2026

(54) RADIO-FREQUENCY CIRCUIT

(71) Applicant: Murata Manufacturing Co., Ltd., Nagaokakyo-shi (JP)

(72) Inventors: Hiroyuki KANI, Nagaokakyo-shi (JP); Reiji NAKAJIMA, Nagaokakyo-shi (JP); Morio TAKEUCHI, Nagaokakyo-shi (JP)

(73) Assignee: Murata Manufacturing Co., Ltd., Nagaokakyo-shi (JP)

(21) Appl. No.: 19/660,438

(22) Filed: Apr. 28, 2026

Related U.S. Application Data
(63) Continuation of application No. PCT/JP2024/034382, filed on Sep. 26, 2024.

(30) Foreign Application Priority Data
Nov. 2, 2023 (JP) 2023-188841

(51) Int. Cl. H04B 1/00; H04B 1/16

(52) U.S. Cl. CPC H04B 1/0078; H04B 1/006; H04B 1/1615

(57) ABSTRACT

A radio-frequency circuit includes a first switch circuit, a first transmission filter, a first reception filter and a phase adjustment circuit. The first switch circuit includes a first common terminal and a first selection terminal. The phase adjustment circuit is operatively coupled between the first common terminal and the first transmission filter. The first switch circuit and the phase adjustment circuit provide a first signal path in a first mode of operation and a second signal path in a second mode of operation. A first reflection phase of the reception band presented at the first common terminal in the first mode differs from a second reflection phase in the second mode. An amount of phase variation in a transmission band provided by the first signal path is smaller than an amount of phase variation in a transmission band provided by the second signal path.

### CROSS-REFERENCE TO RELATED APPLICATIONS

This application is a continuation application of International Application No. PCT/JP2024/034382, filed on Sep. 26, 2024, which claims priority to Japanese Patent Application No. 2023-188841, filed on Nov. 2, 2023. The entire contents of each of the above-referenced applications are incorporated herein by reference.

### TECHNICAL FIELD

The present disclosure relates to a radio-frequency circuit.

### BACKGROUND ART

Patent Document 1 discloses a radio-frequency front-end circuit (radio-frequency circuit) that is operable in each of a carrier aggregation mode and a single mode and that is capable of suppressing insertion loss caused by a multiplexer when operating in the single mode.

### CITATION LIST

### Patent Document

Patent Document 1: Japanese Unexamined Patent Application Publication No. 2019/154025

### SUMMARY

A radio-frequency circuit according to one aspect of the present disclosure includes a first switch circuit including a first selection terminal and a first common terminal connected to an antenna connection terminal, a first transmission filter having a passband including a transmission band of a first frequency division duplex (FDD) band, a first reception filter having a passband including a reception band of the first FDD band, and a phase adjustment circuit operatively coupled between the first common terminal and the first transmission filter. The first switch circuit and the phase adjustment circuit are configured to provide a first signal path between the first common terminal and the first transmission filter in a first mode of operation such that a first reflection phase of the reception band is presented at the first common terminal, and provide a second signal path between the first common terminal and the first transmission filter in a second mode of operation such that a second reflection phase of the reception band is presented at the first common terminal, the second reflection phase being different from the first reflection phase. An amount of phase variation in the transmission band provided by the first signal path is smaller than an amount of phase variation in the transmission band provided by the second signal path.

A radio-frequency circuit according to one aspect of the present disclosure includes a first switch circuit including a first selection terminal, a second selection terminal, a third selection terminal, and a first common terminal connected to an antenna connection terminal, a first transmission filter connected to the first selection terminal and the second selection terminal and having a passband including a transmission band of a first FDD band, a first reception filter connected to the third selection terminal and having a passband including a reception band of the first FDD band, a first path connecting the first transmission filter to the first selection terminal, and a second path connecting the first transmission filter to the second selection terminal. A first reflection phase of the reception band of the first FDD band when the first transmission filter is viewed from the first common terminal via the first path in a state where the first common terminal is connected to the first selection terminal differs from a second reflection phase of the reception band of the first FDD band when the first transmission filter is viewed from the first common terminal via the second path in a state where the first common terminal is connected to the second selection terminal. In the transmission band of the first FDD band, an amount of phase variation between the first common terminal and the first transmission filter connected via the first path is smaller than an amount of phase variation between the first common terminal and the first transmission filter connected via the second path.

A radio-frequency circuit according to one aspect of the present disclosure includes a first switch circuit including a first selection terminal, a second selection terminal, a third selection terminal, and a first common terminal connected to an antenna connection terminal, a first transmission filter connected to the first selection terminal and the second selection terminal and having a passband including a transmission band of a first FDD band, a first reception filter connected to the third selection terminal and having a passband including a reception band of the first FDD band, and a surface-mount inductor or a surface-mount capacitor connected between the second selection terminal and the first transmission filter. No surface-mount inductor and no surface-mount capacitor are connected between the first selection terminal and the first transmission filter.

A radio-frequency circuit according to one aspect of the present disclosure includes a first switch circuit including a first selection terminal, a second selection terminal, and a first common terminal connected to an antenna connection terminal, a first transmission filter connected to the first selection terminal and having a passband including a transmission band of a first FDD band, a first reception filter connected to the second selection terminal and having a passband including a reception band of the first FDD band, an inductor or a capacitor connected between ground and a path connecting the first transmission filter to the first selection terminal, and a switch connected between the inductor or the capacitor and the path or ground. When a first power class defined by a first maximum output power is applied to the first FDD band, the first switch circuit connects the first common terminal to the first selection terminal, and the switch is opened. When a second power class defined by a second maximum output power lower than the first maximum output power is applied to the first FDD band, the first switch circuit connects the first common terminal to the first selection terminal and the second selection terminal, and the switch is closed.

### BRIEF DESCRIPTION OF DRAWINGS

FIG. 1 is a circuit configuration diagram of a radio-frequency circuit according to Embodiment 1.

FIG. 2A is an example of a circuit configuration diagram of a phase adjustment circuit according to Embodiment 1.

FIG. 2B is an example of a circuit configuration diagram of the phase adjustment circuit according to Embodiment 1.

FIG. 2C is an example of a circuit configuration diagram of the phase adjustment circuit according to Embodiment 1.

FIG. 2D is an example of a circuit configuration diagram of the phase adjustment circuit according to Embodiment 1.

FIG. 2E is an example of a circuit configuration diagram of the phase adjustment circuit according to Embodiment 1.

FIG. 2F is an example of a circuit configuration diagram of the phase adjustment circuit according to Embodiment 1.

FIG. 3 is a Smith chart depicting phase adjustment by the phase adjustment circuit according to Embodiment 1.

FIG. 4 is a circuit configuration diagram illustrating a first communication mode of the radio-frequency circuit according to Embodiment 1.

FIG. 5 is a circuit configuration diagram illustrating a second communication mode of the radio-frequency circuit according to Embodiment 1.

FIG. 6 is a circuit configuration diagram illustrating a third communication mode of the radio-frequency circuit according to Embodiment 1.

FIG. 7 is a circuit configuration diagram illustrating a fourth communication mode of the radio-frequency circuit according to Embodiment 1.

FIG. 8 is a circuit configuration diagram of a radio-frequency circuit according to Embodiment 2.

FIG. 9A is an example of a circuit configuration diagram of a phase adjustment circuit according to Embodiment 2.

FIG. 9B is an example of a circuit configuration diagram of the phase adjustment circuit according to Embodiment 2.

FIG. 10 is a circuit configuration diagram illustrating a first communication mode of the radio-frequency circuit according to Embodiment 2.

FIG. 11 is a circuit configuration diagram illustrating a second communication mode of the radio-frequency circuit according to Embodiment 2.

FIG. 12 is a circuit configuration diagram illustrating a third communication mode of the radio-frequency circuit according to Embodiment 2.

FIG. 13 is a circuit configuration diagram illustrating a fourth communication mode of the radio-frequency circuit according to Embodiment 2.

### DESCRIPTION OF EMBODIMENTS

In a radio-frequency circuit of the related art, such as that of Patent Document 1 described above, the inventors have determined that reception sensitivity may decrease in a frequency division duplex (FDD: Frequency Division Duplex) band. Accordingly, the present disclosure is directed to a radio-frequency circuit capable of suppressing a decrease in reception sensitivity in an FDD band.

Embodiments of the present disclosure will be described hereinafter in detail with reference to the drawings. The embodiments described hereinafter each illustrate a comprehensive or specific example. Numerical values, shapes, materials, constituent elements, arrangements and connection forms of the constituent elements, and the like illustrated in the following embodiments are merely examples, and are not intended to limit the present disclosure.

Each drawing is a schematic diagram in which emphasis, omission, or adjustment of proportions is made as appropriate to illustrate the present disclosure, and is not necessarily drawn to scale, and may differ from actual shapes, positional relationships, and ratios. In each drawing, substantially identical components are denoted by the same reference signs, and redundant description may be omitted or simplified.

In the present disclosure, the term “connected” includes not only direct connection by a connection terminal and/or a wiring conductor, but also electrical connection with another circuit element interposed therebetween. The phrase “A is connected between B and C” means that A is connected in series in a path connecting B and C, and specifically means that one end of A is connected to B and the other end of A is connected to C. The term “terminal” refers to a point at which a conductor in an element ends. When the impedance of a conductor between elements is sufficiently low, the terminal may be construed not only as a single point but also as any point on the conductor between the elements or the entire conductor.

The term “passband of a filter” refers to a portion of a frequency spectrum transmitted by the filter, and is defined as a frequency band in which output power is not attenuated by 3 dB or more from the maximum output power. Accordingly, a high-frequency end and a low-frequency end of the passband of a band pass filter are identified as a higher frequency and a lower frequency of two points at which output power is attenuated by 3 dB from the maximum output power.

The term “reception band” refers to a frequency band used for reception in a communication apparatus, and the term “transmission band” refers to a frequency band used for transmission in the communication apparatus. For example, in a band for frequency division duplex (FDD: Frequency Division Duplex), different frequency bands (an uplink band and a downlink band) are used as the transmission band and the reception band. For example, in a band for time division duplex (TDD: Time Division Duplex), the same frequency band is used as the transmission band and the reception band.

### Embodiment 1

First, Embodiment 1 will be described. A communication apparatus 5 according to the present embodiment can be used to provide wireless connection. For example, the communication apparatus 5 can be implemented in user equipment (UE: User Equipment) in a cellular network (also referred to as a mobile network), such as a mobile phone, a smartphone, a tablet computer, or a wearable device. In another example, wireless connection can be provided to an IoT (Internet of Things) sensor device, a medical/healthcare device, a vehicle, an unmanned aerial vehicle (UAV: Unmanned Aerial Vehicle) (so-called drone), and an automated guided vehicle (AGV: Automated Guided Vehicle) through implementation of the communication apparatus 5. In still another example, wireless connection can also be provided at a wireless access point or a wireless hotspot through implementation of the communication apparatus 5.

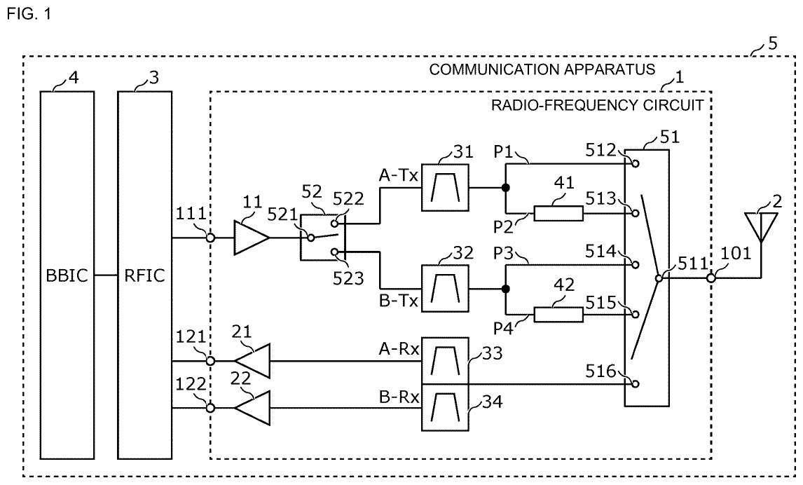

A circuit configuration of the communication apparatus 5 and a circuit configuration of a radio-frequency circuit 1 according to the present embodiment will be described with reference to FIG. 1. FIG. 1 is a circuit configuration diagram of the communication apparatus 5 according to the present embodiment.

FIG. 1 illustrates an exemplary circuit configuration, and the communication apparatus 5 and the radio-frequency circuit 1 may be implemented using any of a wide variety of circuit implementations and circuit technologies. Therefore, the description of the communication apparatus 5 and the radio-frequency circuit 1 provided hereinafter should not be construed in a limiting manner.

### [1.1 Circuit Configuration of Communication Apparatus 5]

First, the circuit configuration of the communication apparatus 5 according to the present embodiment will be described with reference to FIG. 1. The communication apparatus 5 includes the radio-frequency circuit 1, an antenna 2, an RFIC (Radio Frequency Integrated Circuit) 3, and a BBIC (Baseband Integrated Circuit) 4.

The radio-frequency circuit 1 is capable of transmitting a radio-frequency signal between the antenna 2 and the RFIC 3. The circuit configuration of the radio-frequency circuit 1 will be described below.

The antenna 2 is connected to an antenna connection terminal 101 of the radio-frequency circuit 1. The antenna 2 is capable of receiving a radio-frequency signal from the radio-frequency circuit 1 and outputting the radio-frequency signal to the outside of the communication apparatus 5. The antenna 2 is also capable of receiving a radio-frequency signal from the outside of the communication apparatus 5 and outputting the radio-frequency signal to the radio-frequency circuit 1. The antenna 2 need not be included in the communication apparatus 5. The communication apparatus 5 may further include one or more antennas in addition to the antenna 2.

The RFIC 3 is an example of a signal processing circuit that processes a radio-frequency signal. Specifically, the RFIC 3 is capable of performing signal processing such as up-conversion on a transmission signal input from the BBIC 4, and outputting a radio-frequency transmission signal, which is generated by the signal processing, to the radio-frequency circuit 1. Further, the RFIC 3 is capable of performing signal processing such as down-conversion on a radio-frequency reception signal input via a reception path of the radio-frequency circuit 1, and outputting a reception signal, which is generated by the signal processing, to the BBIC 4. The RFIC 3 may include a control unit that controls a switch, a power amplifier, and the like included in the radio-frequency circuit 1. Some or all of the functions of the control unit of the RFIC 3 may be included outside the RFIC 3, and may be included, for example, in the BBIC 4 or the radio-frequency circuit 1. The controller may include control circuitry described in the various embodiments of this disclosure may include hardware such as, but not limited to, processing circuitry, central processing units (CPUs), application specific integrated circuits (ASICs), field programmable gate arrays (FPGAs), conventional circuitry, and/or combinations thereof which are programmed, using one or more programs stored in one or more memories, or otherwise configured to perform the disclosed functionality.

The BBIC 4 is a baseband signal processing circuit that performs signal processing using an intermediate-frequency band having a frequency lower than that of a radio-frequency signal transmitted by the radio-frequency circuit 1. Signals to be processed by the BBIC 4 include, for example, an image signal for image display and/or an audio signal for a call via a speaker. The BBIC 4 need not be included in the communication apparatus 5.

### [1.2 Circuit Configuration of Radio-Frequency Circuit 1]

Next, the circuit configuration of the radio-frequency circuit 1 according to the present embodiment will be described with reference to FIG. 1. The radio-frequency circuit 1 includes a power amplifier 11, low-noise amplifiers 21 and 22, transmission filters 31 and 32, reception filters 33 and 34, phase adjustment circuits 41 and 42, switch circuits 51 and 52, an antenna connection terminal 101, a radio-frequency input terminal 111, and radio-frequency output terminals 121 and 122.

The antenna connection terminal 101 is an external connection terminal of the radio-frequency circuit 1. The antenna connection terminal 101 is connected to the antenna 2 outside the radio-frequency circuit 1, and is connected to the switch circuit 51 inside the radio-frequency circuit 1. Accordingly, via the antenna connection terminal 101, the radio-frequency circuit 1 is capable of supplying a transmission signal to the antenna 2 and receiving a reception signal from the antenna 2.

The radio-frequency input terminal 111 is an external connection terminal of the radio-frequency circuit 1. The radio-frequency input terminal 111 is connected to the RFIC 3 outside the radio-frequency circuit 1, and is connected to the power amplifier 11 inside the radio-frequency circuit 1. Accordingly, the radio-frequency circuit 1 is capable of supplying transmission signals of bands A and B, which are received from the RFIC 3 via the radio-frequency input terminal 111, to the power amplifier 11.

The radio-frequency output terminals 121 and 122 are external connection terminals of the radio-frequency circuit 1. The radio-frequency output terminals 121 and 122 are connected to the RFIC 3 outside the radio-frequency circuit 1, and are connected to the low-noise amplifiers 21 and 22, respectively, inside the radio-frequency circuit 1. Accordingly, the radio-frequency circuit 1 is capable of supplying reception signals of bands A and B from the low-noise amplifiers 21 and 22 to the RFIC 3 via the radio-frequency output terminals 121 and 122.

The power amplifier 11 is connected between the radio-frequency input terminal 111 and the switch circuit 52. Specifically, an input end of the power amplifier 11 is connected to the radio-frequency input terminal 111, and an output end of the power amplifier 11 is connected to the switch circuit 52. The power amplifier 11 is capable of amplifying transmission signals of bands A and B supplied from the RFIC 3 via the radio-frequency input terminal 111, using power supplied from a power source.

The power amplifier 11 can be configured with a heterojunction bipolar transistor (HBT: Heterojunction Bipolar Transistor), and can be manufactured using a semiconductor material. For example, silicon germanium (SiGe) or gallium arsenide (GaAs) can be used as the semiconductor material. The amplifying transistors of the power amplifier 11 are not limited to HBTs. For example, the power amplifier 11 may be configured with a HEMT (High Electron Mobility Transistor) or a MESFET (Metal-Semiconductor Field Effect Transistor). In this case, gallium nitride (GaN) or silicon carbide (SiC) may be used as the semiconductor material.

Part or all of the power amplifier 11 need not be included in the radio-frequency circuit 1. In this case, part or all of the power amplifier 11 may be connected between the RFIC 3 and the radio-frequency input terminal 111, or may be included in the RFIC 3.

The low-noise amplifier 21 is connected between the reception filter 33 and the radio-frequency output terminal 121. Specifically, an input end of the low-noise amplifier 21 is connected to the reception filter 33, and an output end of the low-noise amplifier 21 is connected to the radio-frequency output terminal 121. The low-noise amplifier 21 is capable of amplifying a reception signal of band A that has passed through the reception filter 33, using power supplied from a power source.

The low-noise amplifier 22 is connected between the reception filter 34 and the radio-frequency output terminal 122. Specifically, an input end of the low-noise amplifier 22 is connected to the reception filter 34, and an output end of the low-noise amplifier 22 is connected to the radio-frequency output terminal 122. The low-noise amplifier 22 is capable of amplifying a reception signal of band B that has passed through the reception filter 34, using power supplied from a power source.

The low-noise amplifiers 21 and 22 can be configured with field effect transistors (FETs: Field Effect Transistors), and can be manufactured using a semiconductor material. For example, single-crystal silicon, gallium nitride (GaN), or silicon carbide (SiC) can be used as the semiconductor material. The amplifying transistors of the low-noise amplifiers 21 and 22 are not limited to FETs. For example, part or all of the low-noise amplifiers 21 and 22 may be configured with bipolar transistors.

Part or all of the low-noise amplifier 21 and/or 22 need not be included in the radio-frequency circuit 1. In this case, part or all of the low-noise amplifier 21 may be connected between the radio-frequency output terminal 121 and the RFIC 3, and part or all of the low-noise amplifier 22 may be connected between the radio-frequency output terminal 122 and the RFIC 3. Part or all of the low-noise amplifier 21 and/or 22 may be included in the RFIC 3.

The transmission filter 31 is an example of a first transmission filter, and has a passband including a transmission band of band A. The transmission filter 31 is connected between the switch circuits 51 and 52. Specifically, one end of the transmission filter 31 is connected to a selection terminal 512 of the switch circuit 51 via a path P1, and is also connected to a selection terminal 513 of the switch circuit 51 via a path P2. The other end of the transmission filter 31 is connected to a selection terminal 522 of the switch circuit 52.

A bulk acoustic wave (BAW: Bulk Acoustic Wave) filter can be used as the transmission filter 31. A surface acoustic wave (SAW: Surface Acoustic Wave) filter, an LC resonant filter or a dielectric resonant filter, or any combination of a BAW filter, a SAW filter, an LC resonant filter, and a dielectric resonant filter may be used as the transmission filter 31, and the transmission filter 31 is not limited thereto.

The transmission filter 32 is an example of a second transmission filter, and has a passband including a transmission band of band B. The transmission filter 32 is connected between the switch circuits 51 and 52. Specifically, one end of the transmission filter 32 is connected to a selection terminal 514 of the switch circuit 51 via a path P3, and is also connected to a selection terminal 515 of the switch circuit 51 via a path P4. The other end of the transmission filter 32 is connected to a selection terminal 523 of the switch circuit 52.

A SAW filter can be used as the transmission filter 32. A BAW filter, an LC resonant filter or a dielectric resonant filter, or any combination of a SAW filter, a BAW filter, an LC resonant filter, and a dielectric resonant filter may be used as the transmission filter 32, and the transmission filter 32 is not limited thereto.

The reception filter 33 is an example of a first reception filter, and has a passband including a reception band of band A. The reception filter 33 is connected between the switch circuit 51 and the low-noise amplifier 21. Specifically, one end of the reception filter 33 is connected to a selection terminal 516 of the switch circuit 51, and the other end of the reception filter 33 is connected to the input end of the low-noise amplifier 21. A SAW filter can be used as the reception filter 33. A BAW filter, an LC resonant filter or a dielectric resonant filter, or any combination of a SAW filter, a BAW filter, an LC resonant filter, and a dielectric resonant filter may be used as the reception filter 33, and the reception filter 33 is not limited thereto.

The reception filter 34 is an example of a second reception filter, and has a passband including a reception band of band B. The reception filter 34 is connected between the switch circuit 51 and the low-noise amplifier 22. Specifically, one end of the reception filter 34 is connected to the selection terminal 516 of the switch circuit 51, and the other end of the reception filter 34 is connected to the input end of the low-noise amplifier 22. The reception filter 34 need not be connected to the selection terminal 516, and may be connected to an additional selection terminal of the switch circuit 51. A SAW filter can be used as the reception filter 34. A BAW filter, an LC resonant filter or a dielectric resonant filter, or any combination of a SAW filter, a BAW filter, an LC resonant filter, and a dielectric resonant filter may be used as the reception filter 34, and the reception filter 34 is not limited thereto.

The transmission filter 32 and/or the reception filter 34 need not be included in the radio-frequency circuit 1. That is, the radio-frequency circuit 1 need not support transmission and/or reception of a signal of band B.

Bands A and B are frequency bands for a communication system constructed using radio access technology (RAT: Radio Access Technology). Bands A and B are defined in advance by standardization organizations or the like (e.g., 3GPP (registered trademark) (3rd Generation Partnership Project) and IEEE (Institute of Electrical and Electronics Engineers)). Examples of the communication system include a 5G NR (5th Generation New Radio) system, an LTE (Long Term Evolution) system, and a WLAN (Wireless Local Area Network) system.

Bands A and B are examples of a first FDD band and a second FDD band, respectively. Each of bands A and B corresponds to a first power class. The first power class is defined by a first maximum output power higher than a second maximum output power of a second power class. Specifically, the first power class is, for example, power class 2, and in this case, the first maximum output power is 26 dBm. The second power class is, for example, power class 3, and in this case, the second maximum output power is 23 dBm. The first power class and the second power class are not limited to power class 2 and power class 3. For example, the first power class may be power class 1.5, and the second power class may be power class 5.

One example of such a combination of bands A and B can be a combination of Band 1 for LTE or n1 for 5G NR and Band 3 for LTE or n3 for 5G NR. The combination of bands A and B is not limited thereto. For example, the combination of bands A and B may be a combination of Band 1 for LTE or n1 for 5G NR and Band 40 for LTE or n40 for 5G NR. Alternatively, for example, the combination of bands A and B may be a combination of Band 3 for LTE or n3 for 5G NR and Band 40 for LTE or n40 for 5G NR.

A power class is a classification of output power of a terminal defined by the maximum output power, and indicates that the smaller the value of the power class, the higher the maximum output power is permitted. For example, in 3GPP, maximum output power of power class 1 is defined as 31 dBm, maximum output power of power class 1.5 is defined as 29 dBm, maximum output power of power class 2 is defined as 26 dBm, maximum output power of power class 3 is defined as 23 dBm, and maximum output power of power class 5 is defined as 20 dBm.

Maximum output power of a terminal is defined as the maximum output power at an antenna end. Measurement of maximum output power of UE is performed by a method defined by 3GPP or the like. For example, in FIG. 1, maximum output power is measured by measuring radiated power at the antenna 2. Instead of measurement of radiated power, a terminal is provided in the vicinity of the antenna 2 and a measuring instrument (e.g., a spectrum analyzer or the like) is connected to the terminal, thereby enabling measurement of maximum output power of the antenna 2. The power class is identified by maximum output power measured in this manner.

The phase adjustment circuit 41 is connected between the selection terminal 513 of the switch circuit 51 and the transmission filter 31. The phase adjustment circuit 41 includes an inductor and/or a capacitor. The phase adjustment circuit 41 is capable of adjusting a reflection phase of a reception band of band A when the transmission filter 31 is viewed from a common terminal 511 via the path P2 in a state where the common terminal 511 is connected to the selection terminal 513. A reflection phase adjusted by the phase adjustment circuit 41 (second reflection phase) differs from a reflection phase of the reception band of band A (first reflection phase) when the transmission filter 31 is viewed from the common terminal 511 via the path P1 in a state where the common terminal 511 is connected to the selection terminal 512 in the switch circuit 51.

The phase adjustment circuit 42 is connected between a selection terminal 515 of the switch circuit 51 and the transmission filter 32. The phase adjustment circuit 42 includes an inductor and/or a capacitor. The phase adjustment circuit 42 is capable of adjusting a reflection phase of a reception band of band B when the transmission filter 32 is viewed from the common terminal 511 via the path P4 in a state where the common terminal 511 is connected to the selection terminal 515. A reflection phase adjusted by the phase adjustment circuit 42 (fourth reflection phase) differs from a reflection phase of the reception band of band B (third reflection phase) when the transmission filter 32 is viewed from the common terminal 511 via the path P3 in a state where the common terminal 511 is connected to the selection terminal 514 in the switch circuit 51.

The inductor and/or capacitor included in each of the phase adjustment circuits 41 and 42 may be mounted as a surface mount device (SMD: Surface Mount Device), or may be formed by wiring in or on a module substrate. An inductor and a capacitor mounted as surface mount devices are referred to as a surface-mount inductor and a surface-mount capacitor, respectively. The phase adjustment circuit 41 and/or 42 need not include an inductor and a capacitor, and may be configured by, for example, a transmission line.

The switch circuit 51 is an example of a first switch circuit, and may be referred to as an antenna switch. The switch circuit 51 is connected between the antenna connection terminal 101 and the transmission filters 31 and 32 and the reception filters 33 and 34. Specifically, the switch circuit 51 includes the common terminal 511 and the selection terminals 512 to 516. The common terminal 511 is an example of a first common terminal, and is connected to the antenna connection terminal 101. The selection terminal 512 is an example of a first selection terminal, and is connected to the transmission filter 31 via the path P1. The selection terminal 513 is an example of a second selection terminal, and is connected to the transmission filter 31 via the path P2. The selection terminal 514 is an example of a fourth selection terminal, and is connected to the transmission filter 32 via the path P3. The selection terminal 515 is an example of a fifth selection terminal, and is connected to the transmission filter 32 via the path P4. The selection terminal 516 is an example of a third selection terminal, and is connected to the reception filters 33 and 34.

In such a connection configuration, the switch circuit 51 is capable of connecting the common terminal 511 to at least one of the selection terminals 512 to 516 based on, for example, a control signal from the RFIC 3. That is, in the switch circuit 51, the common terminal 511 can be connected to any of the selection terminals 512 to 516, and can also be simultaneously connected to at least two of the selection terminals 512 to 516. The switch circuit 51 is, for example, a multi-connection-type switch circuit.

The switch circuit 52 is an example of a second switch circuit, and may be referred to as a band-select switch. The switch circuit 52 is connected between the power amplifier 11 and the transmission filters 31 and 32. Specifically, the switch circuit 52 includes a common terminal 521 and the selection terminals 522 and 523. The common terminal 521 is an example of a second common terminal, and is connected to the output end of the power amplifier 11. The selection terminal 522 is an example of a sixth selection terminal, and is connected to the transmission filter 31. The selection terminal 523 is an example of a seventh selection terminal, and is connected to the transmission filter 32.

In such a connection configuration, the switch circuit 52 is capable of exclusively connecting the common terminal 521 to the selection terminal 522 or 523 based on, for example, a control signal from the RFIC 3. The switch circuit 52 is, for example, an SPDT (Single-Pole Double-Throw) type switch circuit.

The switch circuits 51 and 52 may be implemented in, for example, one integrated circuit including a plurality of MOSFETs (Metal-Oxide-Semiconductor Field-Effect Transistors), but an implementation method of the switch circuits 51 and 52 is not limited thereto. For example, the switch circuits 51 and 52 may be separately implemented in two integrated circuits. The switch circuit 51 may be implemented in one integrated circuit together with the phase adjustment circuits 41 and 42.

The path P1 is an example of a first path, and connects the selection terminal 512 and the transmission filter 31. The path P1 is capable of connecting the transmission filter 31 to the selection terminal 512 without passing through the phase adjustment circuit 41. That is, the path P1 is a transmission path that bypasses the phase adjustment circuit 41.

The path P2 is an example of a second path, and connects the selection terminal 513 and the transmission filter 31. The path P2 is capable of connecting the transmission filter 31 to the selection terminal 513 via the phase adjustment circuit 41. That is, the path P2 is a transmission path that passes through the phase adjustment circuit 41.

In this manner, the phase adjustment circuit 41 is connected only to the path P2 of the paths P1 and P2. Accordingly, in a transmission band of band A, an amount of phase variation between the common terminal 511 and the transmission filter 31 connected via the path P1 is smaller than an amount of phase variation between the common terminal 511 and the transmission filter 31 connected via the path P2. That is, in the path P1, loss of a transmission signal of band A can be suppressed more than in the path P2.

The path P3 is an example of a third path, and connects the selection terminal 514 and the transmission filter 32. The path P3 is capable of connecting the transmission filter 32 to the selection terminal 514 without passing through the phase adjustment circuit 42. That is, the path P3 is a transmission path that bypasses the phase adjustment circuit 42.

The path P4 is an example of a fourth path, and connects the selection terminal 515 and the transmission filter 32. The path P4 is capable of connecting the transmission filter 32 to the selection terminal 515 via the phase adjustment circuit 42. That is, the path P4 is a transmission path that passes through the phase adjustment circuit 42.

In this manner, the phase adjustment circuit 42 is connected only to the path P4 of the paths P3 and P4. Accordingly, in a transmission band of band B, an amount of phase variation between the common terminal 511 and the transmission filter 32 connected via the path P3 is smaller than an amount of phase variation between the common terminal 511 and the transmission filter 32 connected via the path P4. That is, in the path P3, loss of a transmission signal of band B can be suppressed more than in the path P4.

The amount of phase variation refers to a phase difference between an input signal and an output signal. For example, the amount of phase variation between the common terminal 511 and the transmission filter 31 connected via the path P1 is identified by a phase difference between an input signal to the path P1 from an output terminal of the transmission filter 31 and an output signal from the common terminal 511. The amount of phase variation can be detected using a phase detector.

### [1.3 Circuit Configuration of Phase Adjustment Circuits 41 and 42]

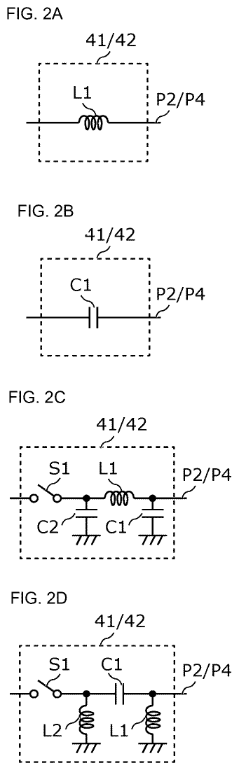

Next, some examples of circuit configurations of the phase adjustment circuits 41 and 42 will be described with reference to FIGS. 2A to 2F. Each of FIGS. 2A to 2F is an exemplary circuit configuration diagram of the phase adjustment circuits 41 and 42 according to the present embodiment.

FIGS. 2A to 2F illustrate exemplary circuit configurations, and the phase adjustment circuits 41 and 42 may be implemented using any of a wide variety of circuit implementations and circuit technologies. Therefore, the description of the phase adjustment circuits 41 and 42 provided hereinafter should not be construed in a limiting manner.

First, FIG. 2A will be described. In FIG. 2A, the phase adjustment circuit 41 and/or 42 includes an inductor L1.

In the phase adjustment circuit 41, the inductor L1 is connected in series with the path P2. Specifically, in the phase adjustment circuit 41, one end of the inductor L1 is connected to the selection terminal 513 of the switch circuit 51, and the other end of the inductor L1 is connected to the transmission filter 31.

In the phase adjustment circuit 42, the inductor L1 is connected in series with the path P4. Specifically, in the phase adjustment circuit 42, one end of the inductor L1 is connected to the selection terminal 515 of the switch circuit 51, and the other end of the inductor L1 is connected to the transmission filter 32.

Next, FIG. 2B will be described. In FIG. 2B, the phase adjustment circuit 41 and/or 42 includes a capacitor C1.

In the phase adjustment circuit 41, the capacitor C1 is connected in series with the path P2. Specifically, in the phase adjustment circuit 41, one end of the capacitor C1 is connected to the selection terminal 513 of the switch circuit 51, and the other end of the capacitor C1 is connected to the transmission filter 31.

In the phase adjustment circuit 42, the capacitor C1 is connected in series with the path P4. Specifically, in the phase adjustment circuit 42, one end of the capacitor C1 is connected to the selection terminal 515 of the switch circuit 51, and the other end of the capacitor C1 is connected to the transmission filter 32.

Next, FIG. 2C will be described. In FIG. 2C, the phase adjustment circuit 41 and/or 42 includes an inductor L1, capacitors C1 and C2, and a switch S1.

In the phase adjustment circuit 41, the inductor L1 and the switch S1 are connected in series with the path P2, and the capacitors C1 and C2 are connected in parallel with the path P2 (shunt connection). Specifically, in the phase adjustment circuit 41, one end of the inductor L1 is connected to the selection terminal 513 of the switch circuit 51, and the other end of the inductor L1 is switchably connected to the transmission filter 31 via the switch S1. The capacitor C1 is connected between ground and a node on the path P2 between the one end of the inductor L1 and the selection terminal 513 of the switch circuit 51, and the capacitor C2 is connected between ground and a node on the path P2 between the other end of the inductor L1 and one end of the switch S1. The one end of the switch S1 is connected to the other end of the inductor L1, and the other end of the switch S1 is connected to the transmission filter 31. The switch S1 is closed (turned on) when the common terminal 511 is connected to the selection terminal 513 in the switch circuit 51, and the switch S1 is opened (turned off) when the common terminal 511 is not connected to the selection terminal 513 in the switch circuit 51.

In the phase adjustment circuit 42, the inductor L1 and the switch S1 are connected in series with the path P4, and the capacitors C1 and C2 are connected in parallel with the path P4. Specifically, in the phase adjustment circuit 42, one end of the inductor L1 is connected to the selection terminal 515 of the switch circuit 51, and the other end of the inductor L1 is switchably connected to the transmission filter 32 via the switch S1. The capacitor C1 is connected between ground and a node on the path P4 between the one end of the inductor L1 and the selection terminal 515 of the switch circuit 51, and the capacitor C2 is connected between ground and a node on the path P4 between the other end of the inductor L1 and one end of the switch S1. The one end of the switch S1 is connected to the other end of the inductor L1, and the other end of the switch S1 is connected to the transmission filter 32. The switch S1 is closed when the common terminal 511 is connected to the selection terminal 515 in the switch circuit 51, and the switch S1 is opened when the common terminal 511 is not connected to the selection terminal 515 in the switch circuit 51.

Next, FIG. 2D will be described. In FIG. 2D, the phase adjustment circuit 41 and/or 42 includes a capacitor C1, inductors L1 and L2, and a switch S1.

In the phase adjustment circuit 41, the capacitor C1 and the switch S1 are connected in series with the path P2, and the inductors L1 and L2 are connected in parallel with the path P2. Specifically, in the phase adjustment circuit 41, one end of the capacitor C1 is connected to the selection terminal 513 of the switch circuit 51, and the other end of the capacitor C1 is switchably connected to the transmission filter 31 via the switch S1. In the phase adjustment circuit 41, the inductor L1 is connected between ground and a node on the path P2 between the one end of the capacitor C1 and the selection terminal 513 of the switch circuit 51, and the inductor L2 is connected between ground and a node on the path P2 between the other end of the capacitor C1 and one end of the switch S1. In the phase adjustment circuit 41, the one end of the switch S1 is connected to the other end of the capacitor C1, and the other end of the switch S1 is connected to the transmission filter 31. The switch S1 is closed when the common terminal 511 is connected to the selection terminal 513 in the switch circuit 51, and the switch S1 is opened when the common terminal 511 is not connected to the selection terminal 513 in the switch circuit 51.

In the phase adjustment circuit 42, the capacitor C1 and the switch S1 are connected in series with the path P4, and the inductors L1 and L2 are connected in parallel with the path P4. Specifically, in the phase adjustment circuit 42, one end of the capacitor C1 is connected to the selection terminal 515 of the switch circuit 51, and the other end of the capacitor C1 is switchably connected to the transmission filter 32 via the switch S1. In the phase adjustment circuit 42, the inductor L1 is connected between ground and a node on the path P4 between the one end of the capacitor C1 and the selection terminal 515 of the switch circuit 51, and the inductor L2 is connected between ground and a node on the path P4 between the other end of the capacitor C1 and one end of the switch S1. In the phase adjustment circuit 42, the one end of the switch S1 is connected to the other end of the capacitor C1, and the other end of the switch S1 is connected to the transmission filter 32. The switch S1 is closed when the common terminal 511 is connected to the selection terminal 515 in the switch circuit 51, and the switch S1 is opened when the common terminal 511 is not connected to the selection terminal 515 in the switch circuit 51.

Next, FIG. 2E will be described. In FIG. 2E, the phase adjustment circuit 41 and/or 42 includes inductors L1 and L2, a capacitor C1, and a switch S1.

In the phase adjustment circuit 41, the inductors L1 and L2 and the switch S1 are connected in series with the path P2, and the capacitor C1 is connected in parallel with the path P2. Specifically, in the phase adjustment circuit 41, one end of the inductor L1 is connected to the selection terminal 513 of the switch circuit 51, and the other end of the inductor L1 is connected to one end of the inductor L2. The one end of the inductor L2 is connected to the other end of the inductor L1, and the other end of the inductor L2 is switchably connected to the transmission filter 31 via the switch S1. The capacitor C1 is connected between ground and a node on the path P2 between the other end of the inductor L1 and the one end of the inductor L2. One end of the switch S1 is connected to the other end of the inductor L2, and the other end of the switch S1 is connected to the transmission filter 31. The switch S1 is closed when the common terminal 511 is connected to the selection terminal 513 in the switch circuit 51, and the switch S1 is opened when the common terminal 511 is not connected to the selection terminal 513 in the switch circuit 51.

In the phase adjustment circuit 42, the inductors L1 and L2 and the switch S1 are connected in series with the path P4, and the capacitor C1 is connected in parallel with the path P4. Specifically, in the phase adjustment circuit 42, one end of the inductor L1 is connected to the selection terminal 515 of the switch circuit 51, and the other end of the inductor L1 is connected to one end of the inductor L2. The one end of the inductor L2 is connected to the other end of the inductor L1, and the other end of the inductor L2 is switchably connected to the transmission filter 32 via the switch S1. The capacitor C1 is connected between ground and a node on the path P4 between the other end of the inductor L1 and the one end of the inductor L2. One end of the switch S1 is connected to the other end of the inductor L2, and the other end of the switch S1 is connected to the transmission filter 32. The switch S1 is closed when the common terminal 511 is connected to the selection terminal 515 in the switch circuit 51, and the switch S1 is opened when the common terminal 511 is not connected to the selection terminal 515 in the switch circuit 51.

Next, FIG. 2F will be described. In FIG. 2F, the phase adjustment circuit 41 and/or 42 includes capacitors C1 and C2, an inductor L1, and a switch S1.

In the phase adjustment circuit 41, the capacitors C1 and C2 and the switch S1 are connected in series with the path P2, and the inductor L1 is connected in parallel with the path P2. Specifically, in the phase adjustment circuit 41, one end of the capacitor C1 is connected to the selection terminal 513 of the switch circuit 51, and the other end of the capacitor C1 is connected to one end of the capacitor C2. The one end of the capacitor C2 is connected to the other end of the capacitor C1, and the other end of the capacitor C2 is switchably connected to the transmission filter 31 via the switch S1. The inductor L1 is connected between ground and a node on the path P2 between the other end of the capacitor C1 and the one end of the capacitor C2. One end of the switch S1 is connected to the other end of the capacitor C2, and the other end of the switch S1 is connected to the transmission filter 31. The switch S1 is closed when the common terminal 511 is connected to the selection terminal 513 in the switch circuit 51, and the switch S1 is opened when the common terminal 511 is not connected to the selection terminal 513 in the switch circuit 51.

In the phase adjustment circuit 42, the capacitors C1 and C2 and the switch S1 are connected in series with the path P4, and the inductor L1 is connected in parallel with the path P4. Specifically, in the phase adjustment circuit 42, one end of the capacitor C1 is connected to the selection terminal 515 of the switch circuit 51, and the other end of the capacitor C1 is connected to one end of the capacitor C2. The one end of the capacitor C2 is connected to the other end of the capacitor C1, and the other end of the capacitor C2 is switchably connected to the transmission filter 32 via the switch S1. The inductor L1 is connected between ground and a node on the path P4 between the other end of the capacitor C1 and the one end of the capacitor C2. One end of the switch S1 is connected to the other end of the capacitor C2, and the other end of the switch S1 is connected to the transmission filter 32. The switch S1 is closed when the common terminal 511 is connected to the selection terminal 515 in the switch circuit 51, and the switch S1 is opened when the common terminal 511 is not connected to the selection terminal 515 in the switch circuit 51.

The circuit configurations of the phase adjustment circuits 41 and 42 may be different from each other. For example, the circuit configuration of the phase adjustment circuit 41 may be one of the circuit configurations of FIGS. 2A to 2F, and the circuit configuration of the phase adjustment circuit 42 may be another one of the circuit configurations of FIGS. 2A to 2F. The circuit configurations of the phase adjustment circuits 41 and 42 may be the same.

### [1.4 Phase Adjustment by Phase Adjustment Circuit 41]

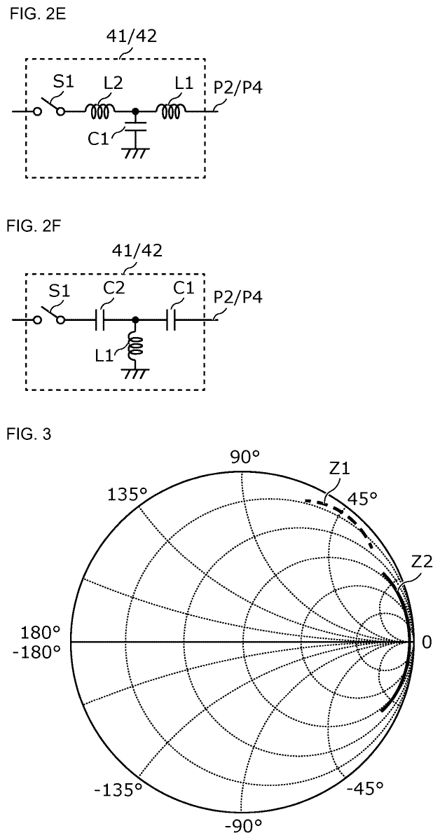

Next, phase adjustment by the phase adjustment circuit 41 will be described with reference to FIG. 3. FIG. 3 is a Smith chart depicting phase adjustment by the phase adjustment circuit 41 according to the present embodiment. Phase adjustment by the phase adjustment circuit 42 is similar to that by the phase adjustment circuit 41, and thus description thereof will be omitted. FIG. 3 is an exemplary Smith chart, and the description of phase adjustment by the phase adjustment circuit 41 provided hereinafter should not be construed in a limiting manner.

In FIG. 3, an impedance Z1 represents the impedance of a reception band of band A when the transmission filter 31 is viewed from the common terminal 511 via the path P1 in a state where the common terminal 511 is connected to the selection terminal 512. An impedance Z2 represents the impedance of the reception band of band A when the transmission filter 31 is viewed from the common terminal 511 via the path P2 in a state where the common terminal 511 is connected to the selection terminal 513.

As illustrated in FIG. 3, a phase (reflection phase) of the impedance Z2 is adjusted by the phase adjustment circuit 41 so as to be a phase different from a phase (reflection phase) of the impedance Z1. Specifically, the phase of the impedance Z2 is closer to 0 degrees than the phase of the impedance Z1. Accordingly, the impedance of the reception band of band A when the transmission filter 31 is viewed from the common terminal 511 via the path P2 can be brought closer to an open state, and leakage of a reception signal of band A from the common terminal 511 to the transmission filter 31 via the path P2 can be suppressed.

The reflection phase refers to a phase difference between a radio-frequency signal and a reflected wave signal detected from a port on which the radio-frequency signal is incident. The reflection phase of the reception band of band A when the transmission filter 31 is viewed from the common terminal 511 via the path P1 in a state where the common terminal 511 is connected to the selection terminal 512, and the reflection phase of the reception band of band A when the transmission filter 31 is viewed from the common terminal 511 via the path P2 in a state where the common terminal 511 is connected to the selection terminal 513 can be identified by measuring the impedance of band A using a network analyzer.

### [1.5 Communication Modes of Radio-Frequency Circuit 1]

Next, communication modes of the radio-frequency circuit 1 corresponding to a band to be used for communication and a power class to be applied to the band will be described.

### [1.5.1 First Communication Mode]

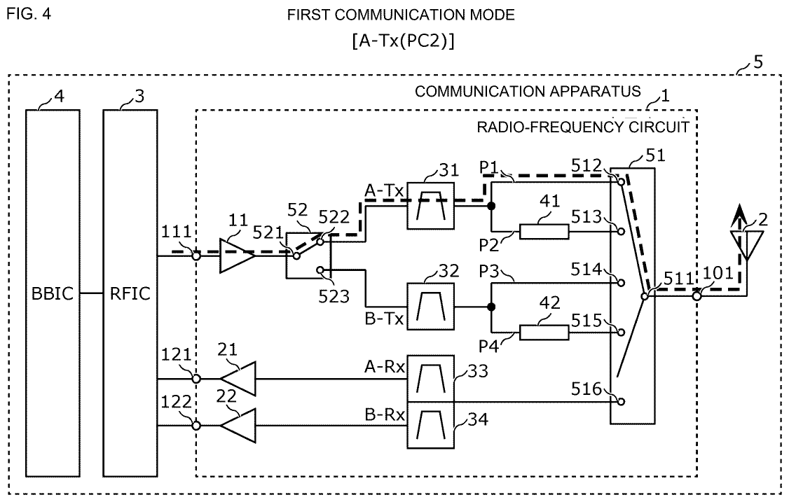

First, a first communication mode of the radio-frequency circuit 1 will be described with reference to FIG. 4. FIG. 4 is a circuit configuration diagram illustrating the first communication mode of the radio-frequency circuit 1 according to the present embodiment. In this drawing and the subsequent drawings, dashed arrows represent a flow of a radio-frequency signal.

The first communication mode is a communication mode for transmitting a signal of band A in the first power class (e.g., power class 2). In the first communication mode, transmission of a signal of the transmission band of band A is not performed simultaneously with reception of a signal of the reception band of band A.

In the first communication mode, the switch circuit 51 connects the common terminal 511 to the selection terminal 512, and does not connect the common terminal 511 to the selection terminals 513 to 516. Further, the switch circuit 52 connects the common terminal 521 to the selection terminal 522, and does not connect the common terminal 521 to the selection terminal 523. Accordingly, one end of the transmission filter 31 is connected to the antenna connection terminal 101 via the path P1, and the other end of the transmission filter 31 is connected to the power amplifier 11.

As a result, a transmission signal of band A is transmitted to the antenna 2 from the RFIC 3 via the radio-frequency input terminal 111, the power amplifier 11, the switch circuit 52, the transmission filter 31, the path P1, the switch circuit 51, and the antenna connection terminal 101.

### [1.5.2 Second Communication Mode]

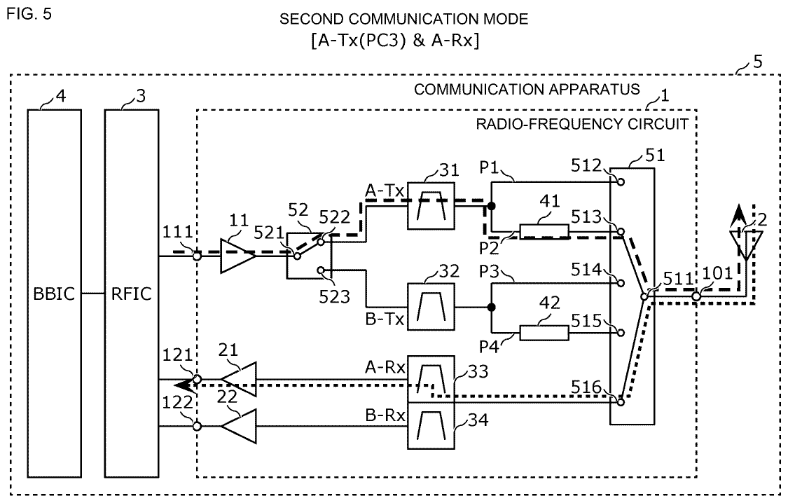

Next, a second communication mode of the radio-frequency circuit 1 will be described with reference to FIG. 5. FIG. 5 is a circuit configuration diagram illustrating the second communication mode of the radio-frequency circuit 1 according to the present embodiment.

The second communication mode is a communication mode for transmitting and receiving a signal of band A in the second power class (e.g., power class 3). In the second communication mode, transmission of a signal of the transmission band of band A is performed simultaneously with reception of a signal of the reception band of band A.

In the second communication mode, the switch circuit 51 connects the common terminal 511 to the selection terminals 513 and 516, and does not connect the common terminal 511 to the selection terminals 512, 514, and 515. Further, the switch circuit 52 connects the common terminal 521 to the selection terminal 522, and does not connect the common terminal 521 to the selection terminal 523. Accordingly, one end of the transmission filter 31 is connected to the antenna connection terminal 101 via the path P2, and the other end of the transmission filter 31 is connected to the power amplifier 11.

As a result, a transmission signal of band A is transmitted to the antenna 2 from the RFIC 3 via the radio-frequency input terminal 111, the power amplifier 11, the switch circuit 52, the transmission filter 31, the path P2, the switch circuit 51, and the antenna connection terminal 101. A reception signal of band A is transmitted to the RFIC 3 from the antenna 2 via the antenna connection terminal 101, the switch circuit 51, the reception filter 33, the low-noise amplifier 21, and the radio-frequency output terminal 121.

### [1.5.3 Third Communication Mode]

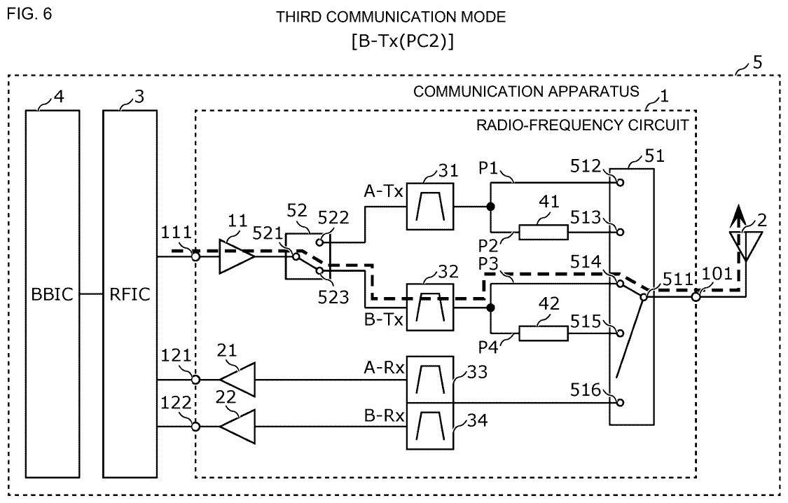

First, a third communication mode of the radio-frequency circuit 1 will be described with reference to FIG. 6. FIG. 6 is a circuit configuration diagram illustrating the third communication mode of the radio-frequency circuit 1 according to the present embodiment. In this drawing and the subsequent drawings, dashed arrows represent a flow of a radio-frequency signal.

The third communication mode is a communication mode for transmitting a signal of band B in the first power class (e.g., power class 2). In the third communication mode, transmission of a signal of the transmission band of band B is not performed simultaneously with reception of a signal of the reception band of band B.

In the third communication mode, the switch circuit 51 connects the common terminal 511 to the selection terminal 514, and does not connect the common terminal 511 to the selection terminals 512, 513, 515, and 516. Further, the switch circuit 52 connects the common terminal 521 to the selection terminal 523, and does not connect the common terminal 521 to the selection terminal 522. Accordingly, one end of the transmission filter 32 is connected to the antenna connection terminal 101 via the path P3, and the other end of the transmission filter 32 is connected to the power amplifier 11.

As a result, a transmission signal of band B is transmitted to the antenna 2 from the RFIC 3 via the radio-frequency input terminal 111, the power amplifier 11, the switch circuit 52, the transmission filter 32, the path P3, the switch circuit 51, and the antenna connection terminal 101.

### [1.5.4 Fourth Communication Mode]

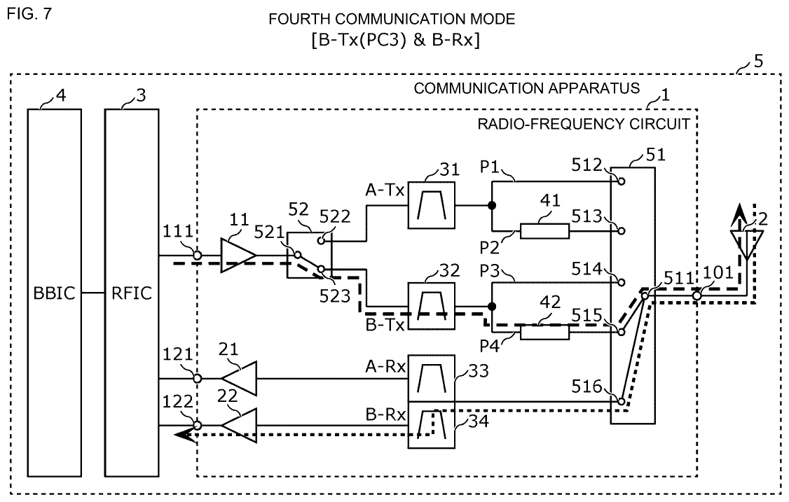

Next, a fourth communication mode of the radio-frequency circuit 1 will be described with reference to FIG. 7. FIG. 7 is a circuit configuration diagram illustrating the fourth communication mode of the radio-frequency circuit 1 according to the present embodiment.

The fourth communication mode is a communication mode for transmitting and receiving a signal of band B in the second power class (e.g., power class 3). In the fourth communication mode, transmission of a signal of the transmission band of band B is performed simultaneously with reception of a signal of the reception band of band B.

In the fourth communication mode, the switch circuit 51 connects the common terminal 511 to the selection terminals 515 and 516, and does not connect the common terminal 511 to the selection terminals 512 to 514. Further, the switch circuit 52 connects the common terminal 521 to the selection terminal 523, and does not connect the common terminal 521 to the selection terminal 522. Accordingly, one end of the transmission filter 32 is connected to the antenna connection terminal 101 via the path P4, and the other end of the transmission filter 32 is connected to the power amplifier 11.

As a result, a transmission signal of band B is transmitted to the antenna 2 from the RFIC 3 via the radio-frequency input terminal 111, the power amplifier 11, the switch circuit 52, the transmission filter 32, the path P4, the switch circuit 51, and the antenna connection terminal 101. A reception signal of band B is transmitted to the RFIC 3 from the antenna 2 via the antenna connection terminal 101, the switch circuit 51, the reception filter 34, the low-noise amplifier 22, and the radio-frequency output terminal 122.

### [1.6 Recapitulation]

As described above, the radio-frequency circuit 1 according to the present embodiment includes the switch circuit 51 including the selection terminals 512, 513, and 516 and the common terminal 511 connected to the antenna connection terminal 101, the transmission filter 31 connected to the selection terminals 512 and 513 and having a passband including a transmission band of band A, the reception filter 33 connected to the selection terminal 516 and having a passband including a reception band of band A, the path P1 connecting the transmission filter 31 to the selection terminal 512, and the path P2 connecting the transmission filter 31 to the selection terminal 513. A first reflection phase of the reception band of band A when the transmission filter 31 is viewed from the common terminal 511 via the path P1 in a state where the common terminal 511 is connected to the selection terminal 512 differs from a second reflection phase of the reception band of band A when the transmission filter 31 is viewed from the common terminal 511 via the path P2 in a state where the common terminal 511 is connected to the selection terminal 513. In the transmission band of band A, an amount of phase variation between the common terminal 511 and the transmission filter 31 connected via the path P1 is smaller than an amount of phase variation between the common terminal 511 and the transmission filter 31 connected via the path P2.

According to this configuration, the radio-frequency circuit 1 is capable of selectively using the two paths P1 and P2 for transmission of a signal of band A. Accordingly, for example, when only transmission of a signal of band A is performed, the path P1 having a smaller amount of phase variation in the transmission band of band A can be selected to reduce loss of a transmission signal of band A, and a reduction in loss of the transmission signal, and the like can be achieved. For example, when transmission and reception of a signal of band A are performed simultaneously, the path P2 having a reflection phase of the reception band that is more suitable can be selected, and leakage of the reception signal into the transmission path can be reduced, thereby improving reception sensitivity.

Further, for example, in the radio-frequency circuit 1 according to the present embodiment, the second reflection phase may be closer to 0 degrees than the first reflection phase.

According to this configuration, the radio-frequency circuit 1 is capable of bringing, closer to an open state, the impedance of the reception band of band A when the transmission filter 31 is viewed from the common terminal 511 via the path P2, and is capable of suppressing leakage of a reception signal of band A from the common terminal 511 to the transmission filter 31 via the path P2.

Furthermore, for example, in the radio-frequency circuit 1 according to the present embodiment, when a first power class (e.g., power class 2) defined by a first maximum output power is applied to band A, the switch circuit 51 may connect the common terminal 511 to the selection terminal 512, and when a second power class (e.g., power class 3) defined by a second maximum output power lower than the first maximum output power is applied to band A, the switch circuit 51 may connect the common terminal 511 to the selection terminals 513 and 516.

According to this configuration, in the first power class, the common terminal 511 is connected to the selection terminal 512, and a signal of band A can be transmitted using the path P1 having a smaller amount of phase variation. Accordingly, the radio-frequency circuit 1 is capable of reducing loss of a transmission signal of band A. On the other hand, in the second power class, the common terminal 511 is connected to the selection terminals 513 and 516, and a signal of band A can be transmitted using the path P2 in which the reflection phase of the reception band of band A is closer to 0 degrees. Accordingly, the radio-frequency circuit 1 is capable of suppressing leakage of the reception signal of band A into the transmission path and improving reception sensitivity. In this manner, the radio-frequency circuit 1 is capable of reducing loss of the transmission signal when transmitting a signal of band A in the first power class, and is capable of suppressing leakage of the reception signal when transmitting and receiving a signal of band A in the second power class. In particular, in the first power class in which higher maximum output power is permitted, the power amplifier 11 lacks sufficient output capacity, and thus an effect of reducing loss of the transmission signal is large.

Furthermore, for example, in the radio-frequency circuit 1 according to the present embodiment, band A may be Band 1 or Band 3 for LTE, or may be n1 or n3 for 5G NR.

According to this configuration, the radio-frequency circuit 1 is capable of supporting transmission and reception of a signal of Band 1 or Band 3 for LTE, or n1 or n3 for 5G NR.

Furthermore, for example, the radio-frequency circuit 1 according to the present embodiment may further include the power amplifier 11 connected to the transmission filter 31.

According to this configuration, the radio-frequency circuit 1 is capable of amplifying a transmission signal of band A.

Furthermore, for example, the radio-frequency circuit 1 according to the present embodiment may further include the reception filter 34 connected to the selection terminal 516 and having a passband including a reception band of band B.

According to this configuration, the radio-frequency circuit 1 is capable of supporting reception of a signal of band B in addition to transmission and reception of a signal of band A.

Furthermore, for example, in the radio-frequency circuit 1 according to the present embodiment, the switch circuit 51 may further include the selection terminals 514 and 515. The radio-frequency circuit 1 may further include the transmission filter 32 connected to the selection terminals 514 and 515 and having a passband including a transmission band of band B, the path P3 connecting the transmission filter 32 to the selection terminal 514, and the path P4 connecting the transmission filter 32 to the selection terminal 515, and a third reflection phase of the reception band of band B when the transmission filter 32 is viewed from the common terminal 511 via the path P3 in a state where the common terminal 511 is connected to the selection terminal 514 may differ from a fourth reflection phase of the reception band of band B when the transmission filter 32 is viewed from the common terminal 511 via the path P4 in a state where the common terminal 511 is connected to the selection terminal 515.

According to this configuration, the radio-frequency circuit 1 is capable of selectively using two paths P3 and P4 for transmission of a signal of band B. Accordingly, for example, when transmission and reception of a signal of band B are performed simultaneously, a path (e.g., the path P4) having a reflection phase of the reception band that is more suitable can be used, and leakage of the reception signal into the transmission path can be reduced, thereby improving reception sensitivity. Conversely, for example, when only transmission of a signal of band B is performed, a path (e.g., the path P3) suitable for transmission of the signal of band B can be selected without taking the reflection phase of the reception band into consideration, and a reduction in loss of the transmission signal, and the like can be achieved.

Furthermore, for example, in the radio-frequency circuit 1 according to the present embodiment, in the transmission band of band B, an amount of phase variation between the common terminal 511 and the transmission filter 32 connected via the path P3 may be smaller than an amount of phase variation between the common terminal 511 and the transmission filter 32 connected via the path P4.

According to this configuration, the radio-frequency circuit 1 is capable of reducing loss of a transmission signal of band B by selecting the path P3.

Furthermore, for example, in the radio-frequency circuit 1 according to the present embodiment, the fourth reflection phase may be closer to 0 degrees than the third reflection phase.

According to this configuration, the radio-frequency circuit 1 is capable of bringing, closer to an open state, the impedance of the reception band of band B when the transmission filter 32 is viewed from the common terminal 511 via the path P4, and is capable of suppressing leakage of a reception signal of band B from the common terminal 511 to the transmission filter 32 via the path P4.

Furthermore, for example, in the radio-frequency circuit 1 according to the present embodiment, when a first power class defined by a first maximum output power is applied to band B, the switch circuit 51 may connect the common terminal 511 to the selection terminal 514, and when a second power class defined by a second maximum output power lower than the first maximum output power is applied to band B, the switch circuit 51 may connect the common terminal 511 to the selection terminals 515 and 516.

According to this configuration, in the first power class, the common terminal 511 is connected to the selection terminal 514, and a signal of band B can be transmitted using the path P3 having a smaller amount of phase variation. Accordingly, the radio-frequency circuit 1 is capable of reducing loss of a transmission signal of band B. On the other hand, in the second power class, the common terminal 511 is connected to the selection terminals 515 and 516, and a signal of band B can be transmitted using the path P4 in which the reflection phase of the reception band of band B is closer to 0 degrees. Accordingly, the radio-frequency circuit 1 is capable of suppressing leakage of the reception signal of band B into the transmission path and improving reception sensitivity. In this manner, the radio-frequency circuit 1 is capable of reducing loss of the transmission signal when transmitting a signal of band B in the first power class, and is capable of suppressing leakage of the reception signal when transmitting and receiving a signal of band B in the second power class. In particular, in the first power class in which higher maximum output power is permitted, the power amplifier 11 lacks sufficient output capacity, and thus an effect of reducing loss of the transmission signal is large.

Furthermore, for example, in the radio-frequency circuit 1 according to the present embodiment, a combination of band A and band B may be a combination of Band 1 for LTE or n1 for 5G NR and Band 3 for LTE or n3 for 5G NR.

According to this configuration, the radio-frequency circuit 1 is capable of supporting transmission and reception of a signal of Band 1 for LTE or n1 for 5G NR, and transmission and reception of a signal of Band 3 for LTE or n3 for 5G NR.

Furthermore, for example, in the radio-frequency circuit 1 according to the present embodiment, the transmission filter 31 may be a bulk acoustic wave filter, and the transmission filter 32 may be a surface acoustic wave filter.

According to this configuration, a BAW filter is used as the transmission filter 31 corresponding to the first power class, thus making it possible to improve electric power handling capability of the transmission filter 31. On the other hand, a SAW filter is used as the reception filter 33, thus making it possible to reduce size and cost of the reception filter 33.

Furthermore, for example, the radio-frequency circuit 1 according to the present embodiment may further include the power amplifier 11, and the switch circuit 52 including the common terminal 521 connected to the power amplifier 11, the selection terminal 522 connected to the transmission filter 31, and the selection terminal 523 connected to the transmission filter 32.

According to this configuration, the power amplifier 11 can be shared for amplification of transmission signals of bands A and B, and it is possible to reduce circuit scale of the radio-frequency circuit 1 as compared with a case where power amplifiers are separately provided for bands A and B.

The radio-frequency circuit 1 according to the present embodiment includes the switch circuit 51 including the selection terminals 512, 513, and 516 and the common terminal 511 connected to the antenna connection terminal 101, the transmission filter 31 connected to the selection terminals 512 and 513 and having a passband including a transmission band of band A, the reception filter 33 connected to the selection terminal 516 and having a passband including a reception band of band A, and a surface-mount inductor (L1) or a surface-mount capacitor (C1) connected between the selection terminal 513 and the transmission filter 31. No surface-mount inductor and no surface-mount capacitor are connected between the selection terminal 512 and the transmission filter 31.

According to this configuration, the radio-frequency circuit 1 is capable of connecting the transmission filter 31 to the common terminal 511 without using the surface-mount inductor and the surface-mount capacitor by connecting the common terminal 511 to the selection terminal 512 in the switch circuit 51. Further, the radio-frequency circuit 1 is capable of connecting the transmission filter 31 to the common terminal 511 via the surface-mount inductor (L1) or the surface-mount capacitor (C1) by connecting the common terminal 511 to the selection terminal 513 in the switch circuit 51. Accordingly, when only transmission of a signal of band A is performed, by connecting the transmission filter 31 to the common terminal 511 without using the surface-mount inductor and the surface-mount capacitor, signal loss due to the surface-mount inductor and the surface-mount capacitor can be avoided. On the other hand, when transmission and reception of a signal of band A are performed simultaneously, by connecting the transmission filter 31 to the common terminal 511 via the surface-mount inductor (L1) or the surface-mount capacitor (C1), it is possible to bring, closer to an open state, the impedance of the reception band of band A when the transmission filter 31 is viewed from the common terminal 511, and it is possible to suppress leakage of the reception signal of band A into the transmission path.

### Embodiment 2

Next, Embodiment 2 will be described. The present embodiment mainly differs from Embodiment 1 described above in that phase adjustment circuits are shunt-connected to transmission paths and each transmission filter is connected to a single selection terminal of an antenna switch. The present embodiment will be described hereinafter with reference to the drawings, focusing on differences from Embodiment 1.

A communication apparatus 5A according to the present embodiment can be used to provide wireless connection, as in Embodiment 1.

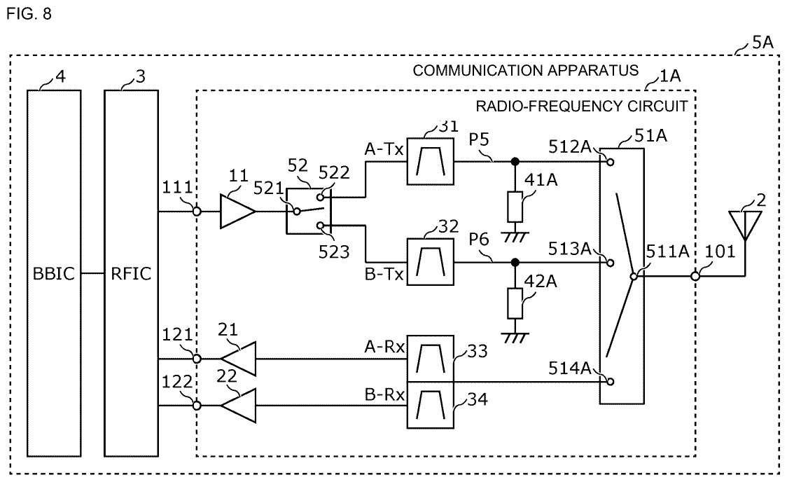

A circuit configuration of the communication apparatus 5A and a circuit configuration of a radio-frequency circuit 1A according to the present embodiment will be described with reference to FIG. 8. FIG. 8 is a circuit configuration diagram of the communication apparatus 5A according to the present embodiment.

FIG. 8 illustrates an exemplary circuit configuration, and the communication apparatus 5A and the radio-frequency circuit 1A may be implemented using any of a wide variety of circuit implementations and circuit technologies. Therefore, the description of the communication apparatus 5A and the radio-frequency circuit 1A provided hereinafter should not be construed in a limiting manner.

### [2.1 Circuit Configuration of Communication Apparatus 5A]

The communication apparatus 5A is similar to that of Embodiment 1 except that the communication apparatus 5A includes the radio-frequency circuit 1A instead of the radio-frequency circuit 1, and thus detailed description thereof will be omitted.

### [2.2 Circuit Configuration of Radio-Frequency Circuit 1A]

The circuit configuration of the radio-frequency circuit 1A according to the present embodiment will be described with reference to FIG. 8. The radio-frequency circuit 1A includes a power amplifier 11, low-noise amplifiers 21 and 22, transmission filters 31 and 32, reception filters 33 and 34, phase adjustment circuits 41A and 42A, switch circuits 51A and 52, an antenna connection terminal 101, a radio-frequency input terminal 111, and radio-frequency output terminals 121 and 122.

The phase adjustment circuit 41A is connected between ground and a path P5 connecting a selection terminal 512A of the switch circuit 51A and the transmission filter 31, and includes an inductor or a capacitor and a switch. The phase adjustment circuit 41A is capable of adjusting, by opening and closing the switch, a reflection phase of the reception band of band A when the transmission filter 31 is viewed from a common terminal 511A in a state where the common terminal 511A is connected to the selection terminal 512A. A reflection phase when the switch of the phase adjustment circuit 41A is closed is closer to 0 degrees than a reflection phase when the switch is opened. Accordingly, by closing the switch, it is possible to bring, closer to an open state, the impedance of the reception band of band A when the transmission filter 31 is viewed from the common terminal 511A, and it is possible to suppress leakage of a reception signal of band A from the common terminal 511A to the transmission filter 31.

The phase adjustment circuit 42A is connected between ground and a path P6 connecting a selection terminal 513A of the switch circuit 51A and the transmission filter 32, and includes an inductor or a capacitor and a switch. The phase adjustment circuit 42A is capable of adjusting, by opening and closing the switch, a reflection phase of the reception band of band B when the transmission filter 32 is viewed from the common terminal 511A in a state where the common terminal 511A is connected to the selection terminal 513A. A reflection phase when the switch of the phase adjustment circuit 42A is closed is closer to 0 degrees than a reflection phase when the switch is opened. Accordingly, by closing the switch, it is possible to bring, closer to an open state, the impedance of the reception band of band B when the transmission filter 32 is viewed from the common terminal 511A, and it is possible to suppress leakage of a reception signal of band B from the common terminal 511A to the transmission filter 32.

The switch circuit 51A is an example of a first switch circuit, and may be referred to as an antenna switch. The switch circuit 51A is connected between the antenna connection terminal 101 and the transmission filters 31 and 32 and the reception filters 33 and 34. Specifically, the switch circuit 51A includes the common terminal 511A and selection terminals 512A to 514A. The common terminal 511A is an example of a first common terminal, and is connected to the antenna connection terminal 101. The selection terminal 512A is an example of a first selection terminal, and is connected to the transmission filter 31. The selection terminal 513A is connected to the transmission filter 32. The selection terminal 514A is an example of a second selection terminal, and is connected to the reception filters 33 and 34.

In such a connection configuration, the switch circuit 51A is capable of connecting the common terminal 511A to at least one of the selection terminals 512A to 514A based on, for example, a control signal from the RFIC 3. That is, the switch circuit 51A is capable of connecting the common terminal 511A to any of the selection terminals 512A to 514A, and is also capable of simultaneously connecting the common terminal 511A to at least two of the selection terminals 512A to 514A. The switch circuit 51A is, for example, a multi-connection-type switch circuit.

### [2.3 Circuit Configuration of Phase Adjustment Circuits 41A and 42A]

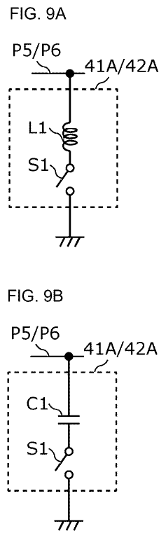

Next, some examples of circuit configurations of the phase adjustment circuits 41A and 42A will be described with reference to FIGS. 9A and 9B. Each of FIGS. 9A and 9B is an exemplary circuit configuration diagram of the phase adjustment circuits 41A and 42A according to the present embodiment.

FIGS. 9A and 9B illustrate exemplary circuit configurations, and the phase adjustment circuits 41A and 42A may be implemented using any of a wide variety of circuit implementations and circuit technologies. Therefore, the description of the phase adjustment circuits 41A and 42A provided hereinafter should not be construed in a limiting manner.

First, FIG. 9A will be described. In FIG. 9A, the phase adjustment circuit 41A and/or 42A includes an inductor L1 and a switch S1.

In the phase adjustment circuit 41A, the inductor L1 is connected between ground and the path P5 connecting the selection terminal 512A of the switch circuit 51A and the transmission filter 31. Specifically, in the phase adjustment circuit 41A, one end of the inductor L1 is connected to the path P5, and the other end of the inductor L1 is connected to ground via the switch S1. The switch S1 is connected between the inductor L1 and ground. The switch S1 may be connected between the inductor L1 and the path P5.

In the phase adjustment circuit 42A, the inductor L1 is connected between ground and the path P6 connecting the selection terminal 513A of the switch circuit 51A and the transmission filter 32. Specifically, in the phase adjustment circuit 42A, one end of the inductor L1 is connected to the path P6, and the other end of the inductor L1 is connected to ground via the switch S1. The switch S1 is connected between the inductor L1 and ground. The switch S1 may be connected between the inductor L1 and the path P6.

Next, FIG. 9B will be described. In FIG. 9B, the phase adjustment circuit 41A and/or 42A includes a capacitor C1 and the switch S1.

In the phase adjustment circuit 41A, the capacitor C1 is connected between ground and the path P5 connecting the selection terminal 512A of the switch circuit 51A and the transmission filter 31. Specifically, in the phase adjustment circuit 41A, one end of the capacitor C1 is connected to the path P5, and the other end of the capacitor C1 is connected to ground via the switch S1. The switch S1 is connected between the capacitor C1 and ground. The switch S1 may be connected between the capacitor C1 and the path P5.

In the phase adjustment circuit 42A, the capacitor C1 is connected between ground and the path P6 connecting the selection terminal 513A of the switch circuit 51A and the transmission filter 32. Specifically, in the phase adjustment circuit 42A, one end of the capacitor C1 is connected to the path P6, and the other end of the capacitor C1 is connected to ground via the switch S1. The switch S1 is connected between the capacitor C1 and ground. The switch S1 may be connected between the capacitor C1 and the path P6.

### [2.4 Communication Modes of Radio-Frequency Circuit 1A]

Next, communication modes of the radio-frequency circuit 1A corresponding to a band to be used and a power class to be applied to the band will be described.

### [2.4.1 First Communication Mode]

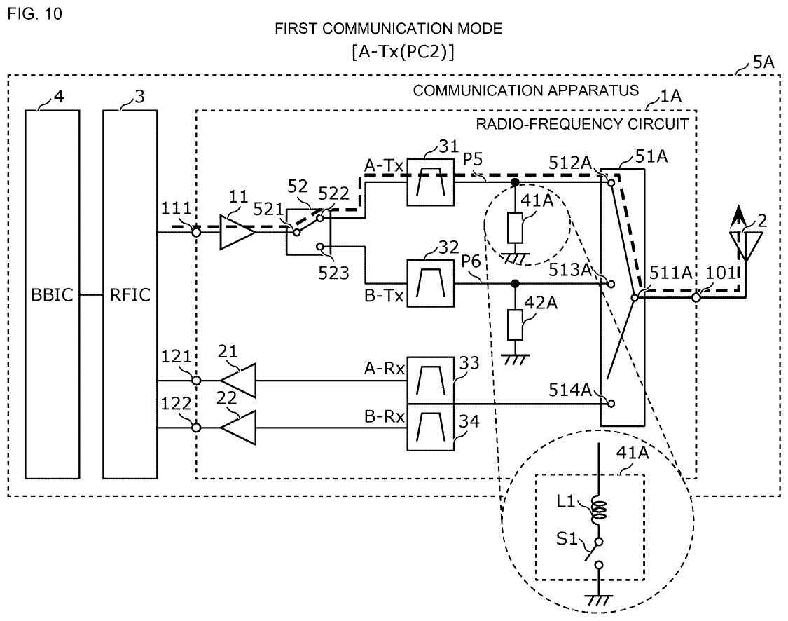

First, a first communication mode of the radio-frequency circuit 1A will be described with reference to FIG. 10. FIG. 10 is a circuit configuration diagram illustrating the first communication mode of the radio-frequency circuit 1A according to the present embodiment. In FIG. 10 and the subsequent drawings, the phase adjustment circuit 41A of FIG. 9A is used as the phase adjustment circuit 41A. However, the phase adjustment circuit 41A of FIG. 9B may be used.

The first communication mode is a communication mode for transmitting a signal of band A in the first power class (e.g., power class 2). In the first communication mode, transmission of a signal of the transmission band of band A is not performed simultaneously with reception of a signal of the reception band of band A.

In the first communication mode, the switch circuit 51A connects the common terminal 511A to the selection terminal 512A, and does not connect the common terminal 511A to the selection terminal 514A. The switch circuit 52 connects the common terminal 521 to the selection terminal 522, and does not connect the common terminal 521 to the selection terminal 523. The phase adjustment circuit 41A opens the switch S1. Accordingly, one end of the transmission filter 31 is connected to the antenna connection terminal 101, and the other end of the transmission filter 31 is connected to the power amplifier 11. Further, the path P5 is not connected to ground via the inductor L1 or the capacitor C1 of the phase adjustment circuit 41A.

As a result, a transmission signal of band A is transmitted to the antenna 2 from the RFIC 3 via the radio-frequency input terminal 111, the power amplifier 11, the switch circuit 52, the transmission filter 31, the path P5, the switch circuit 51A, and the antenna connection terminal 101.

### [2.4.2 Second Communication Mode]

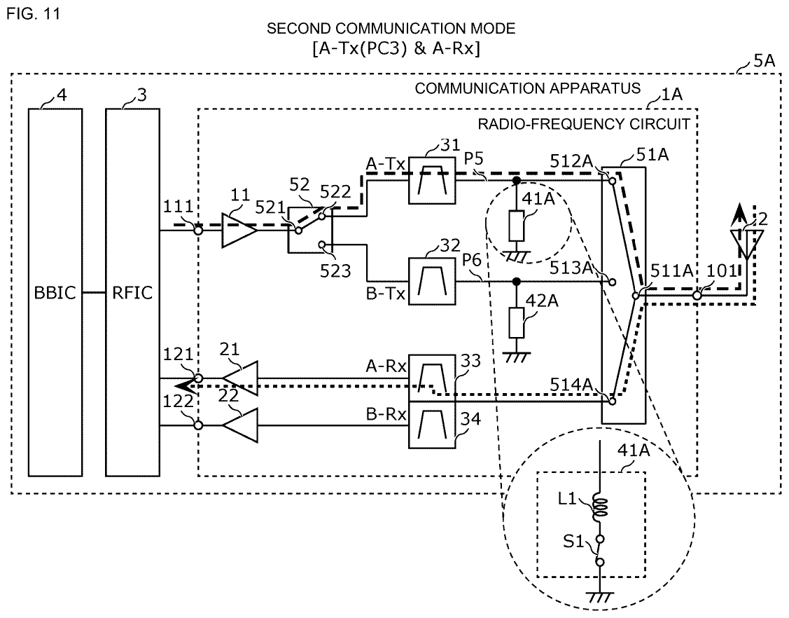

Next, a second communication mode of the radio-frequency circuit 1A will be described with reference to FIG. 11. FIG. 11 is a circuit configuration diagram illustrating the second communication mode of the radio-frequency circuit 1A according to the present embodiment.

The second communication mode is a communication mode for transmitting and receiving a signal of band A in the second power class (e.g., power class 3). In the second communication mode, transmission of a signal of the transmission band of band A is performed simultaneously with reception of a signal of the reception band of band A.

In the second communication mode, the switch circuit 51A connects the common terminal 511A to the selection terminals 512A and 514A. The switch circuit 52 connects the common terminal 521 to the selection terminal 522, and does not connect the common terminal 521 to the selection terminal 523. The phase adjustment circuit 41A closes the switch S1. Accordingly, one end of the transmission filter 31 is connected to the antenna connection terminal 101, and the other end of the transmission filter 31 is connected to the power amplifier 11. Further, the path P5 is connected to ground via the inductor L1 or the capacitor C1 of the phase adjustment circuit 41A, and a reflection phase when the transmission filter 31 is viewed from the common terminal 511A is adjusted by the phase adjustment circuit 41A.

As a result, a transmission signal of band A is transmitted to the antenna 2 from the RFIC 3 via the radio-frequency input terminal 111, the power amplifier 11, the switch circuit 52, the transmission filter 31, the path P5, the switch circuit 51A, and the antenna connection terminal 101. A reception signal of band A is transmitted to the RFIC 3 from the antenna 2 via the antenna connection terminal 101, the switch circuit 51A, the reception filter 33, the low-noise amplifier 21, and the radio-frequency output terminal 121.

### [2.4.3 Third Communication Mode]

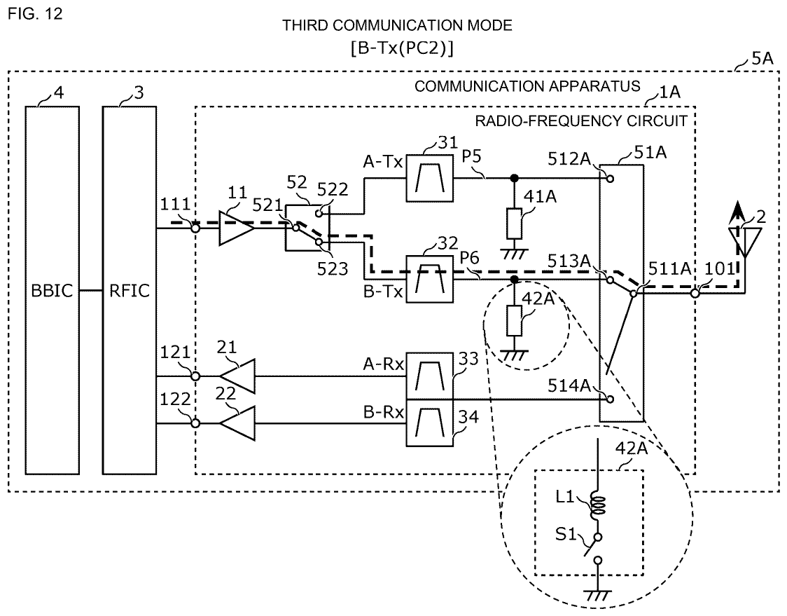

First, a third communication mode of the radio-frequency circuit 1A will be described with reference to FIG. 12. FIG. 12 is a circuit configuration diagram illustrating the third communication mode of the radio-frequency circuit 1A according to the present embodiment.

The third communication mode is a communication mode for transmitting a signal of band B in the first power class (e.g., power class 2). In the third communication mode, transmission of a signal of the transmission band of band B is not performed simultaneously with reception of a signal of the reception band of band B.

In the third communication mode, the switch circuit 51A connects the common terminal 511A to the selection terminal 513A, and does not connect the common terminal 511A to the selection terminal 514A. The switch circuit 52 connects the common terminal 521 to the selection terminal 523, and does not connect the common terminal 521 to the selection terminal 522. The phase adjustment circuit 42A opens the switch S1. Accordingly, one end of the transmission filter 32 is connected to the antenna connection terminal 101, and the other end of the transmission filter 32 is connected to the power amplifier 11. Further, the path P6 is not connected to ground via the inductor L1 or the capacitor C1 of the phase adjustment circuit 42A.

As a result, a transmission signal of band B is transmitted to the antenna 2 from the RFIC 3 via the radio-frequency input terminal 111, the power amplifier 11, the switch circuit 52, the transmission filter 32, the path P6, the switch circuit 51A, and the antenna connection terminal 101.

### [2.4.4 Fourth Communication Mode]

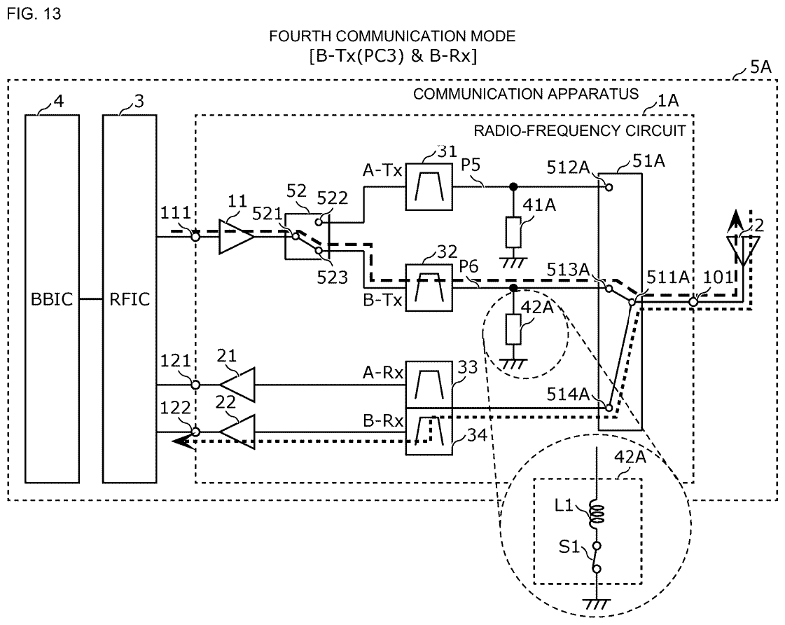

Next, a fourth communication mode of the radio-frequency circuit 1A will be described with reference to FIG. 13. FIG. 13 is a circuit configuration diagram illustrating the fourth communication mode of the radio-frequency circuit 1A according to the present embodiment.

The fourth communication mode is a communication mode for transmitting and receiving a signal of band B in the second power class (e.g., power class 3). In the fourth communication mode, transmission of a signal of the transmission band of band B is performed simultaneously with reception of a signal of the reception band of band B.

In the fourth communication mode, the switch circuit 51A connects the common terminal 511A to the selection terminals 513A and 514A. The switch circuit 52 connects the common terminal 521 to the selection terminal 523, and does not connect the common terminal 521 to the selection terminal 522. The phase adjustment circuit 42A closes the switch S1. Accordingly, one end of the transmission filter 32 is connected to the antenna connection terminal 101, and the other end of the transmission filter 32 is connected to the power amplifier 11. Further, the path P6 is connected to ground via the inductor L1 or the capacitor C1 of the phase adjustment circuit 42A, and a reflection phase when the transmission filter 32 is viewed from the common terminal 511A is adjusted by the phase adjustment circuit 42A.

As a result, a transmission signal of band B is transmitted to the antenna 2 from the RFIC 3 via the radio-frequency input terminal 111, the power amplifier 11, the switch circuit 52, the transmission filter 32, the path P6, the switch circuit 51A, and the antenna connection terminal 101. A reception signal of band B is transmitted to the RFIC 3 from the antenna 2 via the antenna connection terminal 101, the switch circuit 51A, the reception filter 34, the low-noise amplifier 22, and the radio-frequency output terminal 122.

### [2.5 Recapitulation]

As described above, the radio-frequency circuit 1A according to the present embodiment includes the switch circuit 51A including the selection terminals 512A and 514A and the common terminal 511A connected to the antenna connection terminal 101, the transmission filter 31 connected to the selection terminal 512A and having a passband including a transmission band of band A, the reception filter 33 connected to the selection terminal 514A and having a passband including a reception band of band A, the inductor L1 or the capacitor C1 connected between ground and the path P5 connecting the transmission filter 31 to the selection terminal 512A, and the switch S1 connected between the inductor L1 or the capacitor C1 and the path P5 or ground. When a first power class defined by a first maximum output power is applied to band A, the switch circuit 51A connects the common terminal 511A to the selection terminal 512A, and the switch S1 is opened, and when a second power class defined by a second maximum output power lower than the first maximum output power is applied to band A, the switch circuit 51A connects the common terminal 511A to the selection terminals 512A and 514A, and the switch S1 is closed.

According to this configuration, in the first power class, the common terminal 511A is connected to the selection terminal 512A, and the switch S1 is opened. Accordingly, the radio-frequency circuit 1A is capable of suppressing an increase in loss in a transmission path due to the inductor L1 or the capacitor C1, and is capable of reducing loss of a transmission signal of band A. On the other hand, in the second power class, the common terminal 511A is connected to the selection terminals 512A and 514A, and the switch S1 is closed. Accordingly, the radio-frequency circuit 1A is capable of adjusting, by the inductor L1 or the capacitor C1, the reflection phase of the reception band of band A when the transmission filter 31 is viewed from the common terminal 511A, and is capable of suppressing leakage of the reception signal of band A into the transmission path. In this manner, the radio-frequency circuit 1A is capable of reducing loss of the transmission signal when transmitting a signal of band A in the first power class, and is capable of suppressing leakage of the reception signal when transmitting and receiving a signal of band A in the second power class.

In summary, the radio-frequency circuit and communication device described in the various embodiments of the present disclosure provide several technical advantages. By utilizing a switchable phase adjustment circuit—whether implemented through multiple selectable paths or a shunt-connected element—the circuit is capable of dynamically optimizing the reflection phase presented to the antenna connection terminal.

Specifically, in a first mode of operation (such as a high-power transmission mode), the circuit provides a first signal path characterized by low phase variation, thereby minimizing insertion loss and maximizing power efficiency. In a second mode of operation (such as a simultaneous transmission and reception mode), the circuit provides a second signal path that adjusts the reflection phase of the reception band. This phase adjustment increases the impedance of the transmission filter at reception frequencies, effectively suppressing transmission noise leakage into the reception path. Consequently, the disclosure provides a solution that maintains high transmission efficiency while significantly improving reception sensitivity in FDD bands, a combination that is traditionally difficult to achieve in compact radio-frequency front-end architectures.

### Other Embodiments

The radio-frequency circuit according to the present disclosure has been described above based on the embodiments. However, the radio-frequency circuit according to the present disclosure is not limited to the embodiments described above. The present disclosure also encompasses other embodiments obtained by combining any of the constituent elements in the embodiments described above, modifications obtained by applying various changes that would be apparent to a person skilled in the art to the embodiments described above within a range not departing from the gist of the present disclosure, and various devices incorporating the above radio-frequency circuit.

For example, in the circuit configuration of the radio-frequency circuit according to each of the embodiments described above, other circuit elements and wiring or the like may be inserted between each circuit element disclosed in the drawings and a path connecting signal paths. For example, an impedance matching circuit may be inserted between a filter and a switch circuit.

Furthermore, for example, the radio-frequency circuit according to each of the embodiments described above may further include one or more transmission filters and/or reception filters. In this case, the switch circuits 51 and 51A may further include one or more additional selection terminals to which the one or more transmission filters and/or reception filters are connected.

Features of the radio-frequency circuit described above in accordance with the embodiments described above include the following.

<1>

A radio-frequency circuit including:
a first switch circuit including a first selection terminal, a second selection terminal, a third selection terminal, and a first common terminal connected to an antenna connection terminal;
a first transmission filter connected to the first selection terminal and the second selection terminal and having a passband including a transmission band of a first FDD band;
a first reception filter connected to the third selection terminal and having a passband including a reception band of the first FDD band;
a first path connecting the first transmission filter to the first selection terminal; and
a second path connecting the first transmission filter to the second selection terminal, wherein
a first reflection phase of the reception band of the first FDD band when the first transmission filter is viewed from the first common terminal via the first path in a state where the first common terminal is connected to the first selection terminal differs from a second reflection phase of the reception band of the first FDD band when the first transmission filter is viewed from the first common terminal via the second path in a state where the first common terminal is connected to the second selection terminal, and
in the transmission band of the first FDD band, an amount of phase variation between the first common terminal and the first transmission filter connected via the first path is smaller than an amount of phase variation between the first common terminal and the first transmission filter connected via the second path.
   <2>

The radio-frequency circuit according to <1>, wherein the second reflection phase is closer to 0 degrees than the first reflection phase.

<3>

The radio-frequency circuit according to <1> or <2>, wherein
when a first power class defined by a first maximum output power is applied to the first FDD band, the first switch circuit connects the first common terminal to the first selection terminal, and
when a second power class defined by a second maximum output power lower than the first maximum output power is applied to the first FDD band, the first switch circuit connects the first common terminal to the second selection terminal and the third selection terminal.
   <4>

The radio-frequency circuit according to any one of <1> to <3>, wherein
the first FDD band is Band 1 or Band 3 for LTE, or n1 or n3 for 5G NR.
   <5>

The radio-frequency circuit according to any one of <1> to <4>, further including
a power amplifier connected to the first transmission filter.
   <6>

The radio-frequency circuit according to any one of <1> to <4>, further including a second reception filter connected to the third selection terminal and having a passband including a reception band of a second FDD band.

<7>

The radio-frequency circuit according to <6>, wherein
the first switch circuit further includes a fourth selection terminal and a fifth selection terminal, the radio-frequency circuit further includes:
a second transmission filter connected to the fourth selection terminal and the fifth selection terminal and having a passband including a transmission band of the second FDD band;
a third path connecting the second transmission filter to the fourth selection terminal; and
a fourth path connecting the second transmission filter to the fifth selection terminal, and
a third reflection phase of the reception band of the second FDD band when the second transmission filter is viewed from the first common terminal via the third path in a state where the first common terminal is connected to the fourth selection terminal differs from a fourth reflection phase of the reception band of the second FDD band when the second transmission filter is viewed from the first common terminal via the fourth path in a state where the first common terminal is connected to the fifth selection terminal.
   <8>

The radio-frequency circuit according to <7>, wherein
in the transmission band of the second FDD band, an amount of phase variation between the first common terminal and the second transmission filter connected via the third path is smaller than an amount of phase variation between the first common terminal and the second transmission filter connected via the fourth path.
   <9>

The radio-frequency circuit according to <7> or <8>, wherein
the fourth reflection phase is closer to 0 degrees than the third reflection phase.
   <10>

The radio-frequency circuit according to any one of <7> to <9>, wherein
when a first power class defined by a first maximum output power is applied to the second FDD band, the first switch circuit connects the first common terminal to the fourth selection terminal, and
when a second power class defined by a second maximum output power lower than the first maximum output power is applied to the second FDD band, the first switch circuit connects the first common terminal to the third selection terminal and the fifth selection terminal.
   <11>

The radio-frequency circuit according to any one of <7> to <10>, wherein
a combination of the first FDD band and the second FDD band is a combination of Band 1 for LTE or n1 for 5G NR and Band 3 for LTE or n3 for 5G NR.
   <12>

The radio-frequency circuit according to any one of <7> to <11>, wherein
the first transmission filter is a bulk acoustic wave filter, and
the second transmission filter is a surface acoustic wave filter.
   <13>

The radio-frequency circuit according to any one of <7> to <12>, further including:
a power amplifier; and
a second switch circuit including a second common terminal connected to the power amplifier, a sixth selection terminal connected to the first transmission filter, and a seventh selection terminal connected to the second transmission filter.
   <14>

A radio-frequency circuit including:
a first switch circuit including a first selection terminal, a second selection terminal, a third selection terminal, and a first common terminal connected to an antenna connection terminal;
a first transmission filter connected to the first selection terminal and the second selection terminal and having a passband including a transmission band of a first FDD band;
a first reception filter connected to the third selection terminal and having a passband including a reception band of the first FDD band; and
a surface-mount inductor or a surface-mount capacitor connected between the second selection terminal and the first transmission filter, wherein
no surface-mount inductor and no surface-mount capacitor are connected between the first selection terminal and the first transmission filter.
   <15>

A radio-frequency circuit including:
a first switch circuit including a first selection terminal, a second selection terminal, and a first common terminal connected to an antenna connection terminal;
a first transmission filter connected to the first selection terminal and having a passband including a transmission band of a first FDD band;
a first reception filter connected to the second selection terminal and having a passband including a reception band of the first FDD band;
an inductor or a capacitor connected between ground and a path connecting the first transmission filter to the first selection terminal; and
a switch connected between the inductor or the capacitor and the path or ground, wherein
when a first power class defined by a first maximum output power is applied to the first FDD band, the first switch circuit connects the first common terminal to the first selection terminal and the switch is opened, and
when a second power class defined by a second maximum output power lower than the first maximum output power is applied to the first FDD band, the first switch circuit connects the first common terminal to the first selection terminal and the second selection terminal and the switch is closed.

### INDUSTRIAL APPLICABILITY

The present disclosure is directed to a radio-frequency circuit arranged in a front-end section, and can be widely used in communication equipment such as mobile phones.

### REFERENCE SIGNS LIST

1, 1A radio-frequency circuit
2 antenna
3 RFIC
4 BBIC
5, 5A communication apparatus
11 power amplifier
21, 22 low-noise amplifier
31, 32 transmission filter
33, 34 reception filter
41, 41A, 42, 42A phase adjustment circuit
51, 51A, 52 switch circuit
101 antenna connection terminal
111 radio-frequency input terminal
121, 122 radio-frequency output terminal
511, 511A, 521 common terminal
512, 512A, 513, 513A, 514, 514A, 515, 516, 522, 523 selection terminal
C1, C2 capacitor
L1, L2 inductor
P1, P2, P3, P4, P5, P6 path
S1 switch

1. A radio-frequency circuit comprising:
a first switch circuit including a first selection terminal and a first common terminal connected to an antenna connection terminal;
a first transmission filter having a passband including a transmission band of a first frequency division duplex (FDD) band;
a first reception filter having a passband including a reception band of the first FDD band; and
a phase adjustment circuit operatively coupled between the first common terminal and the first transmission filter;
wherein the first switch circuit and the phase adjustment circuit are configured to:
provide a first signal path between the first common terminal and the first transmission filter in a first mode of operation such that a first reflection phase of the reception band is presented at the first common terminal; and
provide a second signal path between the first common terminal and the first transmission filter in a second mode of operation such that a second reflection phase of the reception band is presented at the first common terminal, the second reflection phase being different from the first reflection phase, wherein an amount of phase variation in the transmission band provided by the first signal path is smaller than an amount of phase variation in the transmission band provided by the second signal path.

2. The radio-frequency circuit according to claim 1, wherein
the second reflection phase is closer to 0 degrees than the first reflection phase.

3. The radio-frequency circuit according to claim 1, further comprising
control circuity, wherein
the first switch circuit further includes a second selection terminal and a third selection terminal, in response to a first power class defined by a first maximum output power being applied to the first FDD band, the control circuitry is configured to control the first switch circuit to connect the first common terminal to the first selection terminal, and
in response to a second power class defined by a second maximum output power lower than the first maximum output power being applied to the first FDD band, the control circuitry is configured to control the first switch circuit to connect the first common terminal to the second selection terminal and the third selection terminal.

4. The radio-frequency circuit according to claim 1, wherein
the first FDD band is Band 1 or Band 3 for LTE, or n1 or n3 for 5G NR.

5. The radio-frequency circuit according to claim 1, further comprising
a power amplifier connected to the first transmission filter.

6. The radio-frequency circuit according to claim 1, wherein the first switch circuit further includes a third selection terminal, further comprising
a second reception filter connected to the third selection terminal and having a passband including a reception band of a second FDD band.

7. The radio-frequency circuit according to claim 6, wherein
the first switch circuit further includes a fourth selection terminal and a fifth selection terminal,
the radio-frequency circuit further includes:
a second transmission filter connected to the fourth selection terminal and the fifth selection terminal and having a passband including a transmission band of the second FDD band;
a third signal path connecting the second transmission filter to the fourth selection terminal; and
a fourth signal path connecting the second transmission filter to the fifth selection terminal, and
a third reflection phase of the reception band of the second FDD band when the second transmission filter is viewed from the first common terminal via the third path in a state where the first common terminal is connected to the fourth selection terminal differs from a fourth reflection phase of the reception band of the second FDD band when the second transmission filter is viewed from the first common terminal via the fourth path in a state where the first common terminal is connected to the fifth selection terminal.

8. The radio-frequency circuit according to claim 7, wherein
in the transmission band of the second FDD band, an amount of phase variation between the first common terminal and the second transmission filter connected via the third path is smaller than an amount of phase variation between the first common terminal and the second transmission filter connected via the fourth path.

9. The radio-frequency circuit according to claim 7, wherein
the fourth reflection phase is closer to 0 degrees than the third reflection phase.

10. The radio-frequency circuit according to claim 7, further comprising
control circuity, wherein
in response to a first power class defined by a first maximum output power being applied to the second FDD band, the control circuitry is configured to control the first switch circuit to connect the first common terminal to the fourth selection terminal, and
in response to a second power class defined by a second maximum output power lower than the first maximum output power being applied to the second FDD band, the control circuitry is configured to control the first switch circuit to connect the first common terminal to the third selection terminal and the fifth selection terminal.

11. The radio-frequency circuit according to claim 7, wherein
a combination of the first FDD band and the second FDD band is a combination of Band 1 for LTE or n1 for 5G NR and Band 3 for LTE or n3 for 5G NR.

12. The radio-frequency circuit according to claim 7, wherein
the first transmission filter is a bulk acoustic wave filter, and
the second transmission filter is a surface acoustic wave filter.

13. The radio-frequency circuit according to claim 7, further comprising:
a power amplifier; and
a second switch circuit including a second common terminal connected to the power amplifier, a sixth selection terminal connected to the first transmission filter, and a seventh selection terminal connected to the second transmission filter.

14. The radio-frequency circuit according to claim 1, wherein the phase adjustment circuit includes at least one of a surface-mount inductor and a surface-mount capacitor in the second signal path, and
no surface-mount inductor and no surface-mount capacitor in the first signal path.

15. The radio-frequency circuit according to claim 1, wherein the phase adjustment circuit includes a switch and at least one of an inductor or a capacitor connected in parallel between a ground potential and the first signal path.

16. The radio-frequency circuit according to claim 15, further comprising control circuitry, wherein
in response to a first power class defined by a first maximum output power being applied to the first FDD band, the control circuitry is configured to control the first switch circuit to connect to the first common terminal to the first selection terminal and the switch is opened, and
in response to a second power class defined by a second maximum output power lower than the first maximum output power being applied to the first FDD band, the control circuitry is configured to control the first switch circuit to connect the first common terminal to the first selection terminal and the second selection terminal and the switch is closed.

17. The radio-frequency circuit according to claim 1, wherein the first switch circuit includes a second selection terminal and a third selection terminal, and wherein the first signal path connects the first selection terminal to the first transmission filter and the second signal path connects the second selection terminal to the first transmission filter.

18. The radio-frequency circuit according to claim 1, wherein the first reception filter is connected to a third selection terminal of the first switch circuit, and the first switch circuit is configured to connect the first common terminal to the third selection terminal simultaneously with the first or second selection terminals.

19. The radio-frequency circuit according to claim 1, wherein the amount of phase variation in the transmission band is measured between the first common terminal and the first transmission filter.

20. A mobile communication device comprising:
the radio-frequency circuit according to claim 1;
a baseband signal processing circuit; and
an antenna connected to the antenna connection terminal.
